(19) United States
(12) Patent Application Publication
(10) Pub. No.: US 2023/0411386 A1
(43) Pub. Date: Dec. 21, 2023

(54) METHOD AND STRUCTURE OF FORMING CONTACTS AND GATES FOR STAGGERED FET

(71) Applicant: INTERNATIONAL BUSINESS MACHINES CORPORATION, ARMONK, NY (US)

(72) Inventors: Ruilong Xie, Niskayuna, NY (US); Albert M. Chu, Nashua, NH (US); Junli Wang, Slingerlands, NY (US); Brent A. Anderson, Jericho, VT (US); Anthony I. Chou, Guilderland, NY (US); Dechao Guo, Niskayuna, NY (US)

(21) Appl. No.: 17/807,795

(22) Filed: Jun. 20, 2022

(51) Int. Cl. H01L 27/088; H01L 23/535; H01L 29/06; H01L 29/423; H01L 29/417; H01L 29/786; H01L 29/775; H01L 21/822; H01L 21/8238; H01L 29/66

(52) U.S. Cl. CPC H01L 27/088; H01L 23/535; H01L 29/0673; H01L 29/42392; H01L 29/41733; H01L 29/78618; H01L 29/78696; H01L 29/775; H01L 21/8221; H01L 21/823807; H01L 21/823871; H01L 29/66742; H01L 29/66439

(57) ABSTRACT

A microelectronic structure including a plurality of lower transistors and a plurality of upper transistors, where channels of the upper transistors are staggered from channels of the lower transistors. A lower dielectric pillar located beneath an upper transistor, where the dielectric pillar separates bottom transistors.

### BACKGROUND

The present invention generally relates to the field of microelectronic, and more particularly to formation of an interconnected located in a gate cut, where the interconnected connects at least two components on different devices.

Nanosheet is the lead device architecture in continuing CMOS scaling. However, nanosheet technology has shown issues when scaling down such that as the devices become smaller and closer together, they are interfering with each other. A way to increase the device density is by stacking the devices. However, stacking the devices makes it difficult to form connections to the bottom device and to form shared gate devices.

### BRIEF SUMMARY

Additional aspects and/or advantages will be set forth in part in the description which follows and, in part, will be apparent from the description, or may be learned by practice of the invention.

A microelectronic structure including a plurality of lower transistors and a plurality of upper transistors, where channels of the plurality of upper transistors are staggered from channels of the plurality of lower transistors. A lower dielectric pillar located beneath an upper transistor, where the dielectric pillar separates bottom transistors.

In accordance with an aspect of the present invention where the microelectronic structure includes a bonding oxide located between the plurality of channels of the upper transistor and the lower dielectric pillar.

In accordance with an aspect of the present invention where the microelectronic structure includes an upper dielectric pillar located adjacent to plurality of channels of an upper transistor, where the upper dielectric pillar separates the each of the plurality of upper transistors.

In accordance with an aspect of the present invention where the microelectronic structure includes a portion of the upper dielectric pillar is adjacent to the bonding oxide.

In accordance with an aspect of the present invention where the microelectronic structure includes a first gate surrounds the channels of the lower transistor.

In accordance with an aspect of the present invention where the microelectronic structure includes a second gate surrounds the channels of the upper transistor.

In accordance with an aspect of the present invention where the microelectronic structure includes a gate connection located adjacent to the bonding oxide, where the gate connection is connected to the first gate and the second gate, where the combination of the first gate, the second gate, the gate connection forms a shared gate between the channels of the lower transistor and the channels of the upper transistor.

In accordance with an aspect of the present invention where the microelectronic structure includes the second gate is located between the channel layers of the upper transistor and the upper dielectric pillar.

In accordance with an aspect of the present invention where the microelectronic structure includes a bottom dielectric layer located beneath the channel region of the lower transistors.

In accordance with an aspect of the present invention where the microelectronic structure includes an upper source/drain associated with each of the plurality of upper transistors. A lower source/drain associated with each of the plurality of lower transistors.

In accordance with an aspect of the present invention where the microelectronic structure includes an upper contact that is connected to the upper source/drain.

In accordance with an aspect of the present invention where the microelectronic structure includes a lower contact that is connected to a top surface of the lower source/drain, wherein the lower contact is adjacent to the upper source/drain.

In accordance with an aspect of the present invention where the microelectronic structure includes a shared contact that is connected to a top surface of the upper source/drain and connected to a top surface of the lower source/drain.

A microelectronic structure including a plurality of lower transistors and a plurality of upper transistors, where channels of the plurality of upper transistors are staggered from channels of the plurality of lower transistors. A lower dielectric pillar located beneath an upper transistor, where the dielectric pillar separates bottom transistors. An independent gate surrounding the channels of a first lower transistor, where the independent gate is isolated from the other lower transistors and upper transistors.

In accordance with an aspect of the present invention where the microelectronic structure includes a bonding oxide located between the plurality of channels of the upper transistor and the lower dielectric pillar.

In accordance with an aspect of the present invention where the microelectronic structure includes an upper dielectric pillar located adjacent to the plurality of channels of an upper transistor, wherein the upper dielectric pillar separates the upper transistors.

In accordance with an aspect of the present invention where the microelectronic structure includes a first pair of upper dielectric pillars are located above the first lower transistor.

In accordance with an aspect of the present invention where the microelectronic structure where the independent gate extends between the pair of upper dielectric pillars.

In accordance with an aspect of the present invention where the microelectronic structure includes a portion of the upper dielectric pillar is adjacent to the bonding oxide.

In accordance with an aspect of the present invention where the microelectronic structure includes a first upper transistor is located between a first upper dielectric pillar and a second upper dielectric pillar, where the first upper dielectric pillar is one of the dielectric pillars included in the pair of upper dielectric pillars.

In accordance with an aspect of the present invention where the microelectronic structure includes a second independent gate surrounding the channels of the first upper transistor, where the second independent gate is isolated from the other lower transistors and upper transistors.

A microelectronic structure including a plurality of lower transistors and a plurality of upper transistors, where channels of the plurality of upper transistors are staggered from channels of the plurality of lower transistors. A first independent gate surrounding the channels of a first lower transistor, where the first independent gate is isolated from the other lower transistors and upper transistors. A second independent gate surrounding the channels of a first upper transistor, where the second independent gate is isolated from the other lower transistor and the upper transistors. A shared gate surrounding the channels of a second lower transistor and the channels of a second upper transistor.

A microelectronic structure including a plurality of lower transistors and a plurality of upper transistors, where channels of the plurality of upper transistors are staggered from channels of the plurality of lower transistors. An upper source/drain associated with each of the plurality of upper transistors and a lower source/drain associated with each of the plurality of lower transistors. A lower dielectric pillar located beneath an upper transistor, wherein the dielectric pillar separates bottom transistors. An independent gate surrounding the channels of a first lower transistor, where the independent gate is isolated from the other lower transistors and upper transistors.

In accordance with an aspect of the present invention where the microelectronic structure includes an upper contact that is connected to the upper source/drain. A lower contact that is connected to a top surface of the lower source/drain, wherein the lower contact is adjacent to the upper source/drain.

In accordance with an aspect of the present invention where the microelectronic structure includes a shared contact that is connected to a backside surface of the upper source/drain and connected to a backside surface of the lower source/drain.

### BRIEF DESCRIPTION OF THE DRAWINGS

The above and other aspects, features, and advantages of certain exemplary embodiments of the present invention will be more apparent from the following description taken in conjunction with the accompanying drawings, in which:

FIG. 1 illustrates a top-down view of offset stack devices, in accordance with the embodiment of the present invention.

FIG. 2 illustrates a cross section Y₂ of the source/drain region of the offset stacked device, in accordance with the embodiment of the present invention.

FIG. 3 illustrates a cross section Y₁ and Y3 of gate regions of the offset stacked device, in accordance with the embodiment of the present invention.

FIG. 4 illustrates a cross section Y₂ of the source/drain region of the offset stacked device after the formation of a plurality of bottom gate cuts, in accordance with the embodiment of the present invention.

FIG. 5 illustrates a cross section Y₁ and Y3 of gate regions of the offset stacked device after the formation of a plurality of bottom gate cuts, in accordance with the embodiment of the present invention.

FIG. 6 illustrates a cross section Y₂ of the source/drain region of the offset stacked device after the formation of a bonding oxide, and a plurality of upper source/drains, in accordance with the embodiment of the present invention.

FIG. 7 illustrates a cross section Y₁ and Y3 of gate regions of the offset stacked device after the formation of a bonding oxide, and a plurality of upper nano stacks, in accordance with the embodiment of the present invention.

FIG. 8 illustrates a cross section Y₂ of the source/drain region of the offset stacked device after the formation of a plurality of first trenches, in accordance with the embodiment of the present invention.

FIG. 9 illustrates a cross section Y₁ and Y3 of gate regions of the offset stacked device after the formation of a plurality of first trenches, in accordance with the embodiment of the present invention.

FIG. 10 illustrates a cross section Y₂ of the source/drain region of the offset stacked device after the removal of the dummy gate and the sacrificial layers and the formation of the gate, in accordance with the embodiment of the present invention.

FIG. 11 illustrates a cross section Y₁ and Y3 of gate regions of the offset stacked device after the removal of the dummy gate and the sacrificial layers and the formation of the gate, in accordance with the embodiment of the present invention.

FIG. 12 illustrates a cross section Y₂ of the source/drain region of the offset stacked device after the formation of a plurality of upper gate cuts, in accordance with the embodiment of the present invention.

FIG. 13 illustrates a cross section Y₁ of gate regions of the offset stacked device after the formation of a plurality of upper gate cuts, in accordance with the embodiment of the present invention.

FIG. 14 illustrates a cross section Y3 of gate regions of the offset stacked device after the formation of a plurality of upper gate cuts, in accordance with the embodiment of the present invention.

FIG. 15 illustrates a cross section Y₂ of the source/drain region of the offset stacked device after the formation of a source/drain contacts and electrical connections, in accordance with the embodiment of the present invention.

FIG. 16 illustrates a cross section Y₁ of gate regions of the offset stacked device after the formation of a gate contacts and upper electrical connections, in accordance with the embodiment of the present invention.

FIG. 17 illustrates a cross section Y3 of gate regions of the offset stacked device after the formation of a gate contacts and upper electrical connections, in accordance with the embodiment of the present invention.

FIG. 18 illustrates a cross section Y₂ of the source/drain region of the offset stacked device after the formation of a source/drain contacts and electrical connections, in accordance with the embodiment of the present invention.

FIG. 19 illustrates a cross section Y₂ of the source/drain region of the offset stacked device after the formation of a source/drain contacts and electrical connections, in accordance with the embodiment of the present invention.

FIG. 20 illustrates a cross section Y₁ of gate regions of the offset stacked device after the formation of a gate contacts and upper electrical connections, in accordance with the embodiment of the present invention.

FIG. 21 illustrates a cross section Y3 of gate regions of the offset stacked device after the formation of a gate contacts and upper electrical connections, in accordance with the embodiment of the present invention.

FIG. 22 illustrates a cross section Y₂ of the source/drain region of the offset stacked device after the formation of a source/drain contacts and electrical connections, in accordance with the embodiment of the present invention.

FIG. 23 illustrates a cross section Y₂ of the source/drain region of the offset stacked device after the formation of a source/drain contacts and electrical connections, in accordance with the embodiment of the present invention.

FIG. 24 illustrates a cross section Y₂ of the source/drain region of the offset stacked device, in accordance with the embodiment of the present invention.

FIG. 25 illustrates a cross section Y₁ and Y3 of gate regions of the offset stacked device, in accordance with the embodiment of the present invention.

FIG. 26 illustrates a cross section Y₂ of the source/drain region of the offset stacked device after the formation of a bonding oxide, and a plurality of upper nano stacks, in accordance with the embodiment of the present invention.

FIG. 27 illustrates a cross section Y₁ and Y3 of gate regions of the offset stacked device after the formation of a bonding oxide, and a plurality of upper nano stacks, in accordance with the embodiment of the present invention.

FIG. 28 illustrates a cross section Y₂ of the source/drain region of the offset stacked device after the thinning of upper nano stacks and formation of an upper sacrificial layer, in accordance with the embodiment of the present invention.

FIG. 29 illustrates a cross section Y₁ and Y3 of gate regions of the offset stacked device after the thinning of upper nano stacks and formation of an upper sacrificial layer, in accordance with the embodiment of the present invention.

FIG. 30 illustrates a cross section Y₂ of the source/drain region of the offset stacked device after formation of an upper dielectric spacer and a dielectric core, in accordance with the embodiment of the present invention.

FIG. 31 illustrates a cross section Y₁ and Y3 of gate regions of the offset stacked device after formation of an upper dielectric spacer and a dielectric core, in accordance with the embodiment of the present invention.

FIG. 32 illustrates a cross section Y₂ of the source/drain region of the offset stacked device after the formation of a plurality of upper source/drains and an upper interlayer dielectric layer, in accordance with the embodiment of the present invention.

FIG. 33 illustrates a cross section Y₁ and Y3 of gate regions of the offset stacked device after formation of an upper dummy gate, in accordance with the embodiment of the present invention.

FIG. 34 illustrates a cross section Y₂ of the source/drain region of the offset stacked device after the removal of the upper dummy gate and the dielectric core in the gate region, in accordance with the embodiment of the present invention.

FIG. 35 illustrates a cross section Y₁ and Y3 of gate regions of the offset stacked device after the removal of the upper dummy gate and the dielectric core, in accordance with the embodiment of the present invention.

FIG. 36 illustrates a cross section Y₂ of the source/drain region of the offset stacked device after the formation of a lithography layer and the removal of some of the upper dielectric spacers, in accordance with the embodiment of the present invention.

FIG. 37 illustrates a cross section Y₁ of gate regions of the offset stacked device after the formation of a lithography layer and the removal of some of the upper dielectric spacers, in accordance with the embodiment of the present invention.

FIG. 38 illustrates a cross section Y3 of gate regions of the offset stacked device after the formation of a lithography layer and the removal of some of the upper dielectric spacers, in accordance with the embodiment of the present invention.

FIG. 39 illustrates a cross section Y₂ of the source/drain region of the offset stacked device after the removal of the upper dummy gate, the dummy gate, the sacrificial layers, the bottom spacer, and the upper sacrificial layer, in accordance with the embodiment of the present invention.

FIG. 40 illustrates a cross section Y₁ of gate regions of the offset stacked device after the removal of the upper dummy gate, the dummy gate, the sacrificial layers, the bottom spacer, and the upper sacrificial layer, in accordance with the embodiment of the present invention.

FIG. 41 illustrates a cross section Y3 of gate regions of the offset stacked device after the removal of the upper dummy gate, the dummy gate, the sacrificial layers, the bottom spacer, and the upper sacrificial layer, in accordance with the embodiment of the present invention.

FIG. 42 illustrates a cross section Y₂ of the source/drain region of the offset stacked device after the formation of the gate, in accordance with the embodiment of the present invention.

FIG. 43 illustrates a cross section Y₁ of gate regions of the offset stacked device after the formation of the gate, in accordance with the embodiment of the present invention.

FIG. 44 illustrates a cross section Y3 of gate regions of the offset stacked device after the formation of the gate, in accordance with the embodiment of the present invention.

FIG. 45 illustrates a cross section Y₂ of the source/drain region of the offset stacked device after the formation of source/drain contacts and electrical connections, in accordance with the embodiment of the present invention.

FIG. 46 illustrates a cross section Y₁ of gate regions of the offset stacked device after the formation of gate contacts and electrical connections, in accordance with the embodiment of the present invention.

FIG. 47 illustrates a cross section Y3 of gate regions of the offset stacked device after the formation gate contacts and electrical connections, in accordance with the embodiment of the present invention.

FIG. 48 illustrates a cross section Y₂ of the source/drain region of the offset stacked device after the formation of source/drain contacts and electrical connections, in accordance with the embodiment of the present invention.

### DETAILED DESCRIPTION

The following description with reference to the accompanying drawings is provided to assist in a comprehensive understanding of exemplary embodiments of the invention as defined by the claims and their equivalents. It includes various specific details to assist in that understanding but these are to be regarded as merely exemplary. Accordingly, those of ordinary skill in the art will recognize that various changes and modifications of the embodiments described herein can be made without departing from the scope and spirit of the invention. In addition, descriptions of well-known functions and constructions may be omitted for clarity and conciseness.

The terms and the words used in the following description and the claims are not limited to the bibliographical meanings but are merely used to enable a clear and consistent understanding of the invention. Accordingly, it should be apparent to those skilled in the art that the following description of exemplary embodiments of the present invention is provided for illustration purpose only and not for the purpose of limiting the invention as defined by the appended claims and their equivalents.

It is understood that the singular forms “a,” “an,” and “the” include plural referents unless the context clearly dictates otherwise. Thus, for example, reference to “a component surface” includes reference to one or more of such surfaces unless the context clearly dictates otherwise.

Detailed embodiments of the claimed structures and the methods are disclosed herein: however, it can be understood that the disclosed embodiments are merely illustrative of the claimed structures and methods that may be embodied in various forms. This invention may, however, be embodied in many different forms and should not be construed as limited to the exemplary embodiments set forth herein. Rather, these exemplary embodiments are provided so that this disclosure will be thorough and complete and will fully convey the scope of this invention to those skilled in the art. In the description, details of well-known features and techniques may be omitted to avoid unnecessarily obscuring the present embodiments.

References in the specification to “one embodiment,” “an embodiment,” an example embodiment,” etc., indicate that the embodiment described may include a particular feature, structure, or characteristic, but every embodiment may not include the particular feature, structure, or characteristic. Moreover, such phrases are not necessarily referring to the same embodiment. Further, when a particular feature, structure, or characteristic is described in connection with an embodiment, it is submitted that it is within the knowledge of one of ordinary skill in the art o affect such feature, structure, or characteristic in connection with other embodiments whether or not explicitly described.

For purpose of the description hereinafter, the terms “upper,” “lower,” “right,” “left,” “vertical,” “horizontal,” “top,” “bottom,” and derivatives thereof shall relate to the disclosed structures and methods, as orientated in the drawing figures. The terms “overlying,” “atop,” “on top,” “positioned on,” or “positioned atop” mean that a first element, such as a first structure, is present on a second element, such as a second structure, where intervening elements, such as an interface structure may be present between the first element and the second element. The term “direct contact” means that a first element, such as a first structure, and a second element, such as a second structure, are connected without any intermediary conducting, insulating, or semiconductor layer at the interface of the two elements.

In the interest of not obscuring the presentation of embodiments of the present invention, in the following detailed description, some processing steps or operations that are known in the art may have been combined together for presentation and for illustrative purposes and in some instance may have not been described in detail. In other instances, some processing steps or operations that are known in the art may not be described at all. It should be understood that the following description is rather focused on the distinctive features or elements of various embodiments of the present invention.

Various embodiments of the present invention are described herein with reference to the related drawings. Alternative embodiments can be devised without departing from the scope of this invention. It is noted that various connections and positional relationships (e.g., over, below, adjacent, etc.) are set forth between elements in the following description and in the drawings. These connections and/or positional relationships, unless specified otherwise, can be direct or indirect, and the present invention is not intended to be limiting in this respect. Accordingly, a coupling of entities can refer to either a direct or indirect coupling, and a positional relationship between entities can be direct or indirect positional relationship. As an example of indirect positional relationship, references in the present description to forming layer “A” over layer “B” includes situations in which one or more intermediate layers (e.g., layer “C”) is between layer “A” and layer “B” as long as the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains,” or “containing” or any other variation thereof, are intended to cover a non-exclusive inclusion. For example, a composition, a mixture, process, method, article, or apparatus that comprises a list of elements is not necessarily limited to only those elements but can include other element not expressly listed or inherent to such composition, mixture, process, method, article, or apparatus.

Additionally, the term “exemplary” is used herein to mean “serving as an example, instance or illustration.” Any embodiment or design described herein as “exemplary” is not necessarily to be construed as preferred or advantageous over other embodiment or designs. The terms “at least one” and “one or more” can be understood to include any integer number greater than or equal to one, i.e., one, two, three, four, etc. The terms “a plurality” can be understood to include any integer number greater than or equal to two, i.e., two, three, four, five, etc. The term “connection” can include both indirect “connection” and a direct “connection.”

As used herein, the term “about” modifying the quantity of an ingredient, component, or reactant of the invention employed refers to variation in the numerical quantity that can occur, for example, through typical measuring and liquid handling procedures used for making concentrations or solutions. Furthermore, variation can occur from inadvertent error in measuring procedures, differences in manufacture, source, or purity of the ingredients employed to make the compositions or carry out the methods, and the like. The terms “about” or “substantially” are intended to include the degree of error associated with measurement of the particular quantity based upon the equipment available at the time of the filing of the application. For example, about can include a range of ±8%, or 5%, or 2% of a given value. In another aspect, the term “about” means within 5% of the reported numerical value. In another aspect, the term “about” means within 10, 9, 8, 7, 6, 5, 4, 3, 2, or 1% of the reported numerical value.

Various processes are used to form a micro-chip that will packaged into an integrated circuit (IC) fall in four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE), and more recently, atomic layer deposition (ALD) among others. Removal/etching is any process that removes material from the wafer. Examples include etching process (either wet or dry), reactive ion etching (RIE), and chemical-mechanical planarization (CMP), and the like. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implant dopants. Films of both conductors (e.g., aluminum, copper, etc.) and insulators (e.g., various forms of silicon dioxide, silicon nitride, etc.) are used to connect and isolate electrical components. Selective doping of various regions of the semiconductor substrate allows the conductivity of the substrate to be changed with the application of voltage.

Reference will now be made in detail to the embodiments of the present invention, examples of which are illustrated in the accompanying drawings, where like reference numerals refer to like elements throughout. The present invention is directed toward stacked FET, but not where the upper device and lower device are vertically aligned. The upper device is offset or staggered from the lower device, such that the vertical center of the upper device is not located above a bottom device. The present invention is directed toward creating a shared gate between the bottom device and the offset upper device. Furthermore, the present invention is directed to create an independent gate upper device and an independent gate lower device along with the shared gate device. The present invention is also directed to forming the gate contacts and the source/drain contacts.

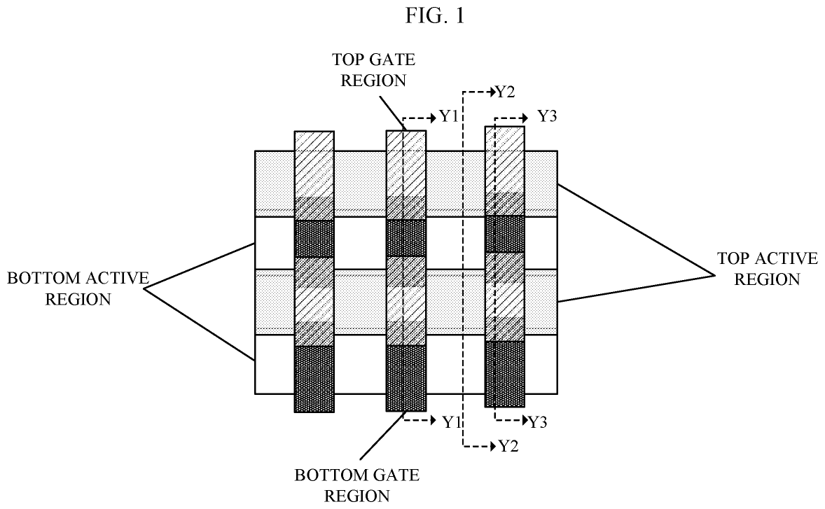

FIG. 1 illustrates a top-down view of offset stack devices, in accordance with the embodiment of the present invention. The present invention is comprised of one or more offset stacked devices, having a plurality of bottom devices and a plurality of offset upper devices. The offset stacked devices are separated from adjacent stack devices by a gate cut filled with a dielectric material. Cross sections Y₁ and Y₃ are vertical cross sections through the gate region of the offset stacked devices. Cross section Y₂ is a vertical cross section through the source/drain region of the offset stacked devices.

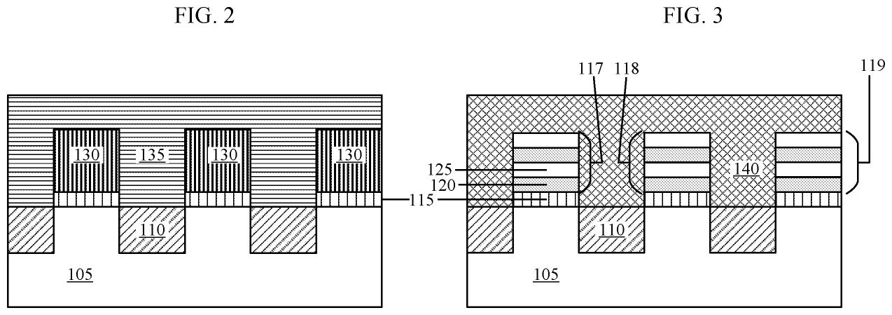

FIGS. 2 and 3 illustrate a process stage after forming bottom active region, shallow trench isolation, dummy gate, bottom dielectric isolation, gate spacer, inner spacer, source/drain epi and interlayer dielectric. FIG. 2 illustrates a cross section Y₂ of the source/drain region of the offset stacked device, in accordance with the embodiment of the present invention. FIG. 3 illustrates a cross section Y₁ and Y3 of gate regions of the offset stacked device, in accordance with the embodiment of the present invention.

The offset device includes a substrate 105, a shallow trench isolation layer 110, a bottom dielectric layer 115, a first bottom nano stack 117, a second bottom nano stack 118, a third bottom nano stack 119, a plurality of bottom source/drains 130. The substrate 105 can be, for example, a material including, but not necessarily limited to, silicon (Si), silicon germanium (SiGe), Si:C (carbon doped silicon), carbon doped silicon germanium (SiGe:C), III-V, II-V compound semiconductor or another like semiconductor. In addition, multiple layers of the semiconductor materials can be used as the semiconductor material of the substrate 105. In some embodiments, the substrate 105 includes both semiconductor materials and dielectric materials. The substrate 105 may also comprise an organic semiconductor or a layered semiconductor such as, for example, Si/SiGe, a silicon-on-insulator or a SiGe-on-insulator. A portion or the entire semiconductor substrate 105 may also be comprised of an amorphous, polycrystalline, or monocrystalline. The substrate 105 may be doped, undoped or contain doped regions and undoped regions therein.

Trenches (not shown) are formed in the substrate 105 when etching the layers to form the plurality of bottom nano stacks 117, 118, 119. These trenches are filled with a shallow trench isolation layer 110.

Each of the plurality of bottom nano stacks 117, 118, 119 includes a plurality of sacrificial layers 120, and a plurality of channel layers 125 (i.e., nanosheets). The plurality of sacrificial layer 120 can be comprised of SiGe, where Ge is in the range of about 15% to 35%. One of the channel layers 125 is located above each of the sacrificial layers 120. A dummy gate 140 is located on top of the shallow trench isolation layer 110 and the dummy gate 140 encloses each of the plurality of bottom nano stacks 117, 118, 119. The dummy gate 140 is in contact with multiple sides of each of the plurality of bottom nano stacks 117, 118, 119. After dummy gate formation, the bottom most sacrificial layer (not shown) under nanosheet stack is removed, and a bottom dielectric layer 115 is formed on the substrate 105 and each of the plurality of bottom nano stacks 117, 118, 119 is located on a section of the bottom dielectric layer 115.

After gate spacer and inner spacer formation (not shown), the plurality of bottom source/drains 130 are located on sections of the bottom dielectric layer 115. Each of the plurality of bottom source/drains 130 corresponds with one of the bottom nano stacks 117, 118, 119, respectively. An interlayer dielectric layer 135 is located on top of the bottom source/drains 130, such that, the interlayer dielectric layer 135 is in contact with multiple sides of each of the plurality of bottom source/drains 130.

The plurality of bottom source/drains 130 can be for example, a n-type epitaxy, or a p-type epitaxy. For n-type epitaxy, an n-type dopant selected from a group of phosphorus (P), arsenic (As) and/or antimony (Sb) can be used. For p-type epitaxy, a p-type dopant selected from a group of boron (B), gallium (Ga), indium (In), and/or thallium (Tl) can be used. Other doping techniques such as ion implantation, gas phase doping, plasma doping, plasma immersion ion implantation, cluster doping, infusion doping, liquid phase doping, solid phase doping, and/or any suitable combination of those techniques can be used. In some embodiments, dopants are activated by thermal annealing such as laser annealing, flash annealing, rapid thermal annealing (RTA) or any suitable combination of those techniques. A bottom interlayer dielectric layer 135 is located on top of the shallow trench isolation layer 110, and the bottom interlayer dielectric layer 135 surrounds each of the plurality of bottom source/drains 130.

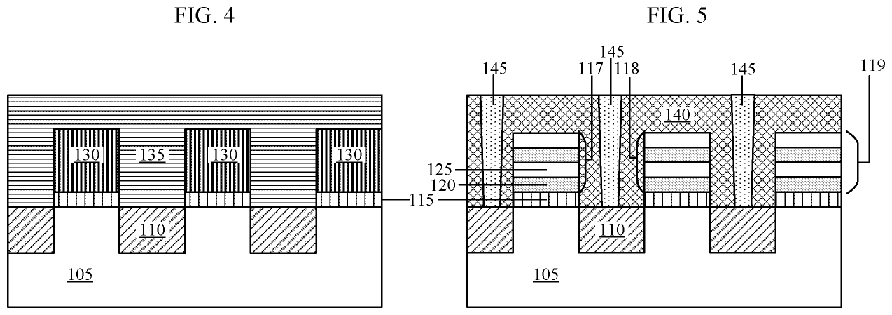

FIGS. 4 and 5 illustrate a process stage after formation of a plurality of bottom gate cuts. FIG. 4 illustrates a cross section Y₂ of the source/drain region of the offset stacked device after the formation of a plurality of bottom gate cuts 145, in accordance with the embodiment of the present invention. FIG. 5 illustrates a cross section Y₁ and Y3 of gate regions of the offset stacked device after the formation of a plurality of bottom gate cuts 145, in accordance with the embodiment of the present invention.

A plurality of bottom gate cuts 145 are formed in the dummy gate 140. The plurality of bottom gate cuts 145 are formed by creating a plurality of trenches (not shown) in the dummy gate 140 and filling the trenches with a dielectric material. The plurality of bottom gate cuts 145 are spaced throughout the dummy gate 140, such that a bottom gate cut 145 is located on each side of one of the bottom nano stacks 117, 118, 199, as illustrated by FIG. 5.

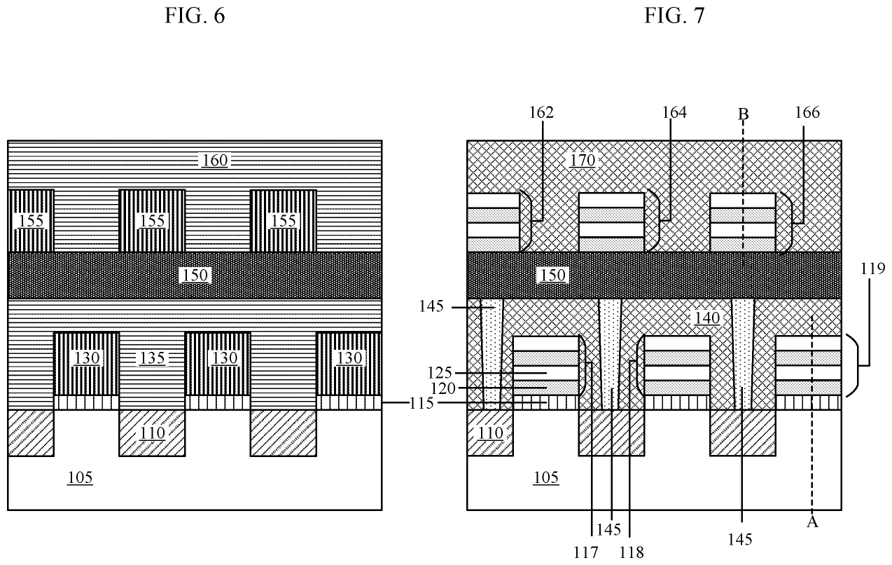

FIGS. 6 and 7 illustrate a process stage after bonding top channel material, patterning top active region, formation of top dummy gate, spacer, inner spacer, source/drain epi and interlayer dielectric. FIG. 6 illustrates a cross section Y₂ of the source/drain region of the offset stacked device after the formation of a bonding oxide 150, and a plurality of upper source/drains, in accordance with the embodiment of the present invention. A bonding oxide 150 is formed on top of the bottom interlayer dielectric layer 135. A plurality of upper source/drains 155 are formed on top of the bonding oxide 150. Each of the plurality of the upper source/drains 155 corresponds to one of the plurality of upper nano stacks 162, 164, 166. A top interlayer dielectric layer 160 is formed on top of the bonding oxide 150 and surrounds each of the plurality of upper source/drains 155. The top interlayer dielectric layer 160 is in contact with multiple sides of each of the plurality of upper source/drains 155.

The plurality of upper source/drains 155 can be for example, a n-type epitaxy, or a p-type epitaxy. For n-type epitaxy, an n-type dopant selected from a group of phosphorus (P), arsenic (As) and/or antimony (Sb) can be used. For p-type epitaxy, a p-type dopant selected from a group of boron (B), gallium (Ga), indium (In), and/or thallium (Tl) can be used. Other doping techniques such as ion implantation, gas phase doping, plasma doping, plasma immersion ion implantation, cluster doping, infusion doping, liquid phase doping, solid phase doping, and/or any suitable combination of those techniques can be used. In some embodiments, dopants are activated by thermal annealing such as laser annealing, flash annealing, rapid thermal annealing (RTA) or any suitable combination of those techniques.

FIG. 7 illustrates a cross section Y₁ and Y3 of gate regions of the offset stacked device after the formation of a bonding oxide 150, and a plurality of upper nano stacks 162, 164, 166, in accordance with the embodiment of the present invention. The bonding oxide 150 is formed on top of the dummy gate 140 and the plurality of bottom gate cuts 145. A plurality of upper nano stacks 162, 164, 166 are formed on top of the bonding oxide 150. Each of the plurality of upper nano stacks 162, 164, 166 are comprised of a plurality of sacrificial layers 120, a plurality of channel layers 125 (i.e., nanosheets). Each of the plurality of upper nano stacks 162, 164, 166 is offset or staggered from the one of the plurality of bottom nano stacks 117, 118, 119. The center vertical axis (i.e., B-axis) of each of the plurality of upper nano stacks 162, 164, 166 is not vertically aligned over the center vertical axis (i.e., A-axis) of the bottom nano stacks 117, 118, 119. The center vertical axis (i.e., B-axis) of each of the plurality of upper nano stacks 162, 164, 166 can be aligned over one of the bottom gate cuts 145 or over the dummy gate 140. A top dummy gate 170 is formed on top of the bonding oxide 150 and the top dummy gate 170 is in contact with multiple sides of each of the plurality of upper nano stacks 162, 164, 166.

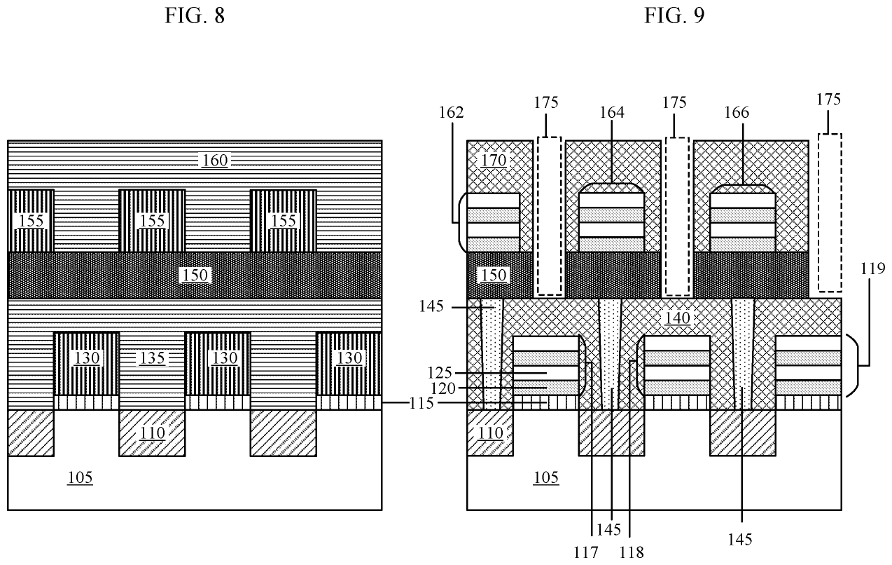

FIGS. 8 and 9 illustrate a process stage after the formation of dummy gate opening trenches. FIG. 8 illustrates a cross section Y₂ of the source/drain region of the offset stacked device after the formation of a plurality of first trenches 175, in accordance with the embodiment of the present invention. FIG. 9 illustrates a cross section Y₁ and Y3 of gate regions of the offset stacked device after the formation of a plurality of first trenches 175, in accordance with the embodiment of the present invention. A plurality of first trenches 175 are created by removing a portion of the top dummy gate 170 and a portion of the bonding oxide 150. A first trench 175 is located between each pair of the upper nano stacks 162, 164, 166. Each of the first trenches 175 extends downwards through the bonding oxide 150 to expose a surface of the dummy gate 140. Each of the plurality of first trenches 175 is vertically aligned with one of the plurality of bottom nano stacks 117, 118, 119, respectively. The plurality of first trenches 175 create a plurality of openings through the bonding oxide 150, where the bonding oxide 150 is divided into multiple sections. Each section of the bonding oxide 150 is located beneath one of the upper nano stacks 162, 164, 166, as illustrated by FIG. 9.

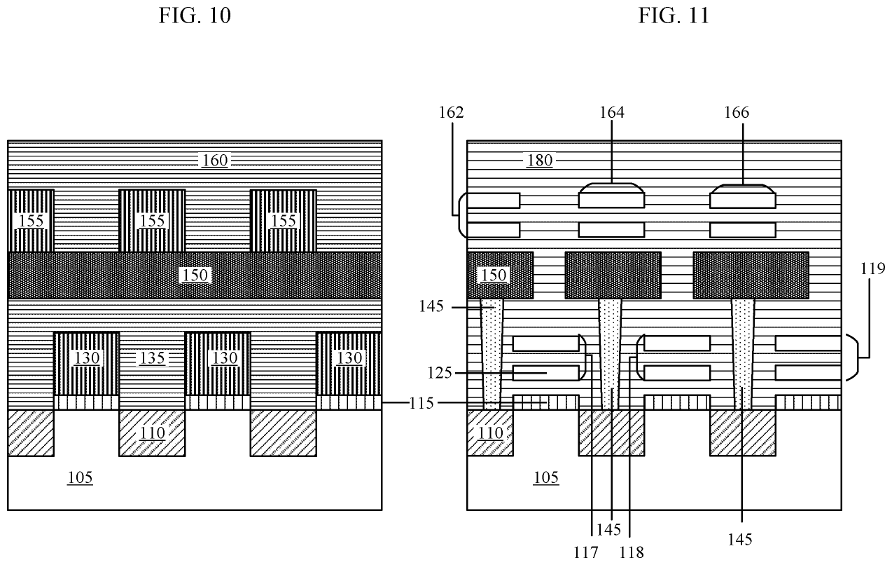

FIGS. 10 and 11 illustrate a process stage after the removal of the dummy gate and the sacrificial layers and the formation of the replacement gate. FIG. 10 illustrates a cross section Y₂ of the source/drain region of the offset stacked device after the removal of the dummy gate and the sacrificial layers and the formation of the gate, in accordance with the embodiment of the present invention. FIG. 11 illustrates a cross section Y₁ and Y3 of gate regions of the offset stacked device after the removal of the dummy gate and the sacrificial layers and the formation of the gate, in accordance with the embodiment of the present invention. The top dummy gate 170, the dummy gate 140 and the sacrificial layers 120 in each of the nano stacks is selectively removed. A gate 180 is formed by depositing a gate material in the space created by the removal of the dummy gate 170, the dummy gate 140 and the sacrificial layers 120. The gate 180 can be comprised of, for example, a gate dielectric liner, such as high-k dielectric like HfO₂, ZrO₂, HfLₐOₓ, etc., and work function layers, such as TiN, TiAlC, TiC, etc., and conductive metal fills, like W. The gate 180 surrounds each of the plurality of bottom nano stacks 117, 118, 119, and each of the plurality of upper nano stack 162, 164, 166. The gate 180 is continuous between the plurality of bottom nano stacks 117, 118, 119, and the plurality of upper nano stacks 162, 164, 166. The gate 180 is located between sections of the bonding oxide 150. For example, the gate 180 is continuous between the bottom nano stack 117 and the upper nano stacks 162, 164, 166, since at this stage there are no upper gate cuts present that separate each of the upper nano stacks 162, 164, 166.

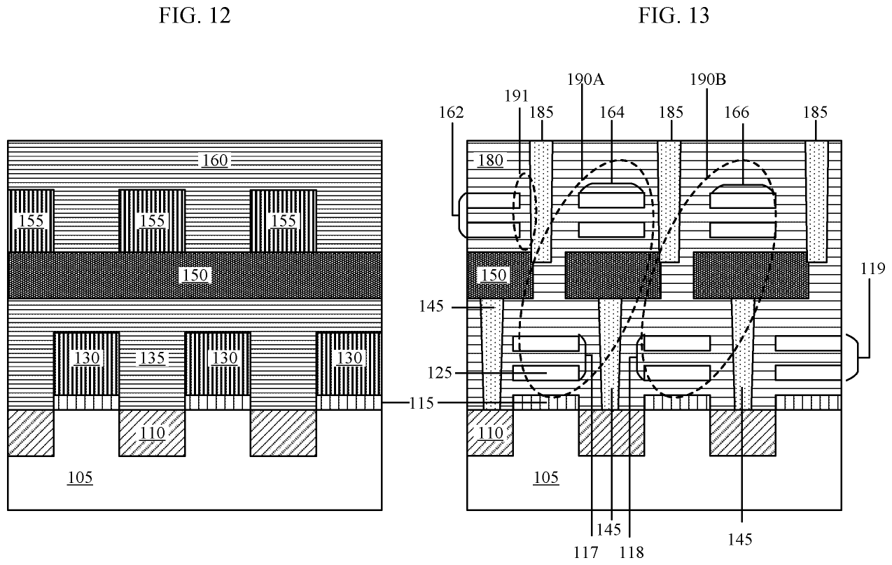

FIGS. 12, 13 and 14 illustrate a process stage after the formation of a plurality of upper gate cuts. FIG. 12 illustrates a cross section Y₂ of the source/drain region of the offset stacked device after the formation of a plurality of upper gate cuts 185, in accordance with the embodiment of the present invention. FIG. 13 illustrates a cross section Y₁ of gate regions of the offset stacked device after the formation of a plurality of upper gate cuts 185, in accordance with the embodiment of the present invention.

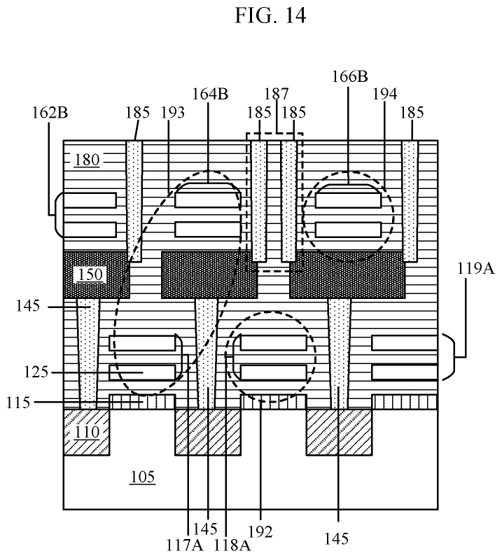

A plurality of trenches (not shown) is formed in the gate 180. The locations of each of the plurality of trenches will determine if a shared gate device or an independent gate device will be created (as illustrated by FIGS. 13 and 14). Each trench is filled with a dielectric material to form a plurality of upper gate cuts 185. As illustrated by FIG. 13, each upper gate cut 185 extends downwards, such that a bottom section of the upper gate cut 185 is directly adjacent to a section of the bonding oxide 150. This means that the bottom section of the upper gate cut 185 is in direct contact with the bonding oxide 150. For example, the middle section of the upper gate cut 185 is space a distance from the channel layers 125 of the first upper nano stack 162. Dashed circle 191, emphasizes that the gate 180 is located between the channel layers 125 of the first upper nano stack 162 and the upper gate cut 185. As illustrated by dashed circle 190A, the upper gate cut 185 is positioned such that the gate 180 is still continuous between the first bottom nano stack 117 and the second upper nano stack 164. As illustrated by dashed circle 190B, the upper gate cut 185 is positioned such that the gate 180 is still continuous between the second bottom nano stack 118 and the third upper nano stack 166.

FIG. 14 illustrates a cross section Y3 of gate regions of the offset stacked device after the formation of a plurality of upper gate cuts 185, in accordance with the embodiment of the present invention. A plurality of trenches (not shown) is formed in the gate 180. The locations of each of the plurality of trenches will determine if a shared gate device or an independent gate device will be created (as illustrated by FIGS. 13 and 14). Each trench is filled with a dielectric material to form a plurality of upper gate cuts 185. Dashed box 187 emphasizes when two upper gate cuts 185 are located between two adjacent upper nano stacks 164B, 166B. The gate 180 is located between the upper gate cuts 185 contained within the dashed box 187, where the gate 180 is located here extends downwards to surround the channel layer 125 of the second bottom nano stack 118A. The two upper gate cuts 185 located within the dashed box 187 allows for the second bottom nano stack 118B and the third upper nano stack 166B to be an independent gate device. Dashed circle 192 emphasizes that the gate 180 surrounding the channel layers 125 of the second bottom nano stack 118A is isolated from the surrounding gate material by the bottom gate cuts 145 and the two upper gate cuts 185 contained in dashed box 187. Dashed circle 194 illustrates how the third upper nano stack 166B is isolated between two of the upper gate cuts 185, thus forming an independent gate device. Dashed circle 193 illustrates the shared gate device between the first bottom nano stack 177A and the second upper nano stack 164B. The first upper nano stack 162B and the third bottom nano stack 119A can be either an independent gate device or a shared gate device.

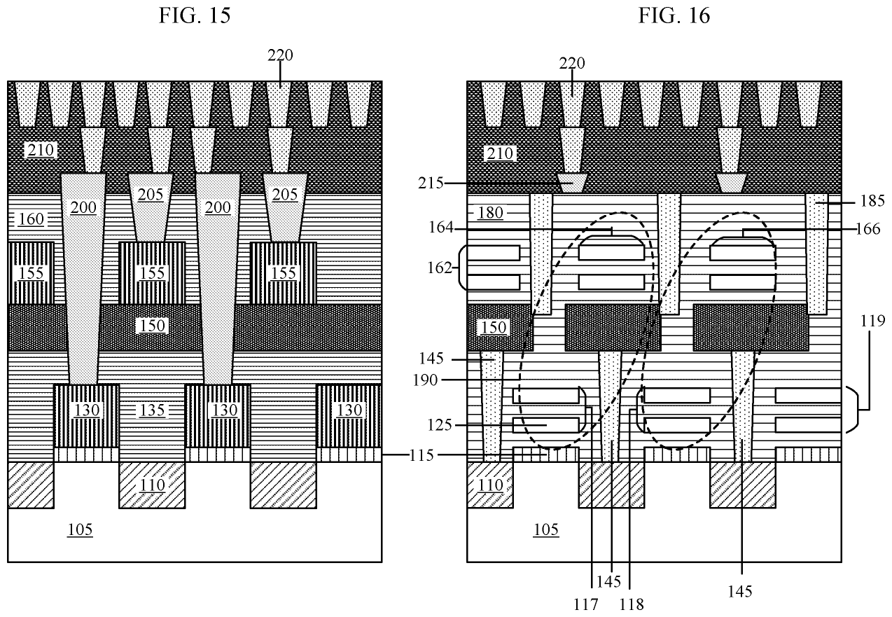

FIGS. 15, 16 and 17 illustrate a process stage after formation of MOL contacts and lower BEOL level. FIG. 15 illustrates a cross section Y₂ of the source/drain region of the offset stacked device after the formation of a source/drain contacts 200, 205 and electrical connections 220, in accordance with the embodiment of the present invention. A top dielectric layer 210 is located on top of the top interlayer dielectric layer 160. Trenches (not shown) are formed in the top layer 210, the top interlayer dielectric layer 160, the bonding oxide 150, and the bottom interlayer dielectric layer 135 to expose a surface of the bottom source drains 130. These trenches are filled with a conductive material to form the bottom source/drain contacts 200. A second set of trenches are created in the top layer 210 and the top interlayer dielectric layer 160 to expose a surface of the upper source/drains 155. These trenches are filled with a conductive material to form the upper source/drain contacts 205. Electrical connections 220 are formed in the top layer 210 and the electrical connections 220 are connected to the bottom source/drain contacts 200 and connected to the upper source/drain contacts 205.

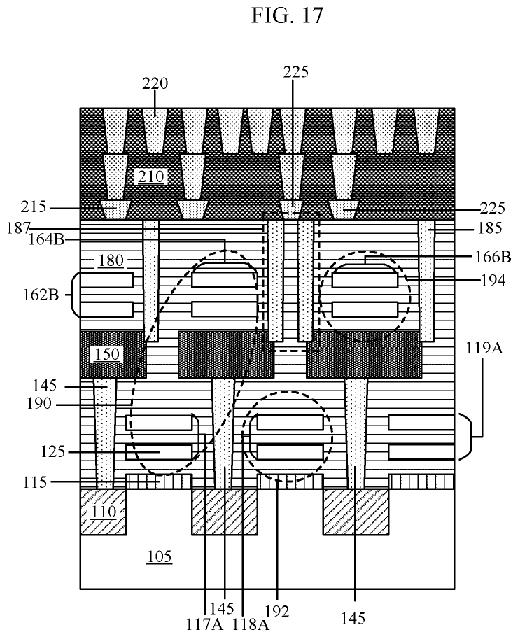

FIG. 16 illustrates a cross section Y₁ of gate regions of the offset stacked device after the formation of a gate contacts and upper electrical connections, in accordance with the embodiment of the present invention. FIG. 17 illustrates a cross section Y3 of gate regions of the offset stacked device after the formation of a gate contacts and upper electrical connections, in accordance with the embodiment of the present invention. A top layer 210 is located on top of the top interlayer dielectric layer 160. Trenches are formed in the top layer 210 and filled with a conductive material to form shared gate contacts 215 and independent gate contacts 225. Electrical connections 220 are formed in the top layer 210 and connected to the shared gate contacts 215 and the independent gate contacts 225.

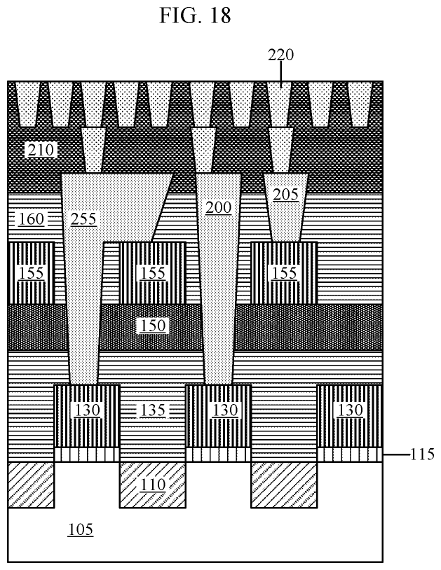

FIG. 18 illustrates another cross section Y₂ of the source/drain region of the offset stacked device after the formation of a source/drain contacts and electrical connections, in accordance with the embodiment of the present invention. A top dielectric layer 210 is located on top of the top interlayer dielectric layer 160. Trenches (not shown) are formed in the top layer 210, the top interlayer dielectric layer 160, the bonding oxide 150, and the bottom interlayer dielectric layer 135 to expose a surface of the bottom source drains 130. These trenches are filled with a conductive material to form the bottom source/drain contacts 200. A second set of trenches are created in the top layer 210 and the top interlayer dielectric layer 160 to expose a surface of the upper source/drains 155. These trenches are filled with a conductive material to form the upper source/drain contacts 205. Additionally, a shared trench can be formed in the top interlayer dielectric 160 that exposes a surface of an upper source/drain 155 and additionally, a via connected to the shared trench is formed in the top interlayer dielectric 160, the bonding oxide 150, and the bottom interlayer dielectric layer 135 that expose a surface of a bottom source/drain 130. The trench and via are filled with a conductive metal to form the shared source/drain contact 255, such that the shared source/drain contact 255 is in direct contact with an upper source/drain 155 and a bottom source/drain 130. Electrical connections 220 are formed in the top layer 210 and the electrical connections 220 are connected to the bottom source/drain contacts 200, connected to the upper source/drain contacts 205, and connected to the share source/drain contact 255.

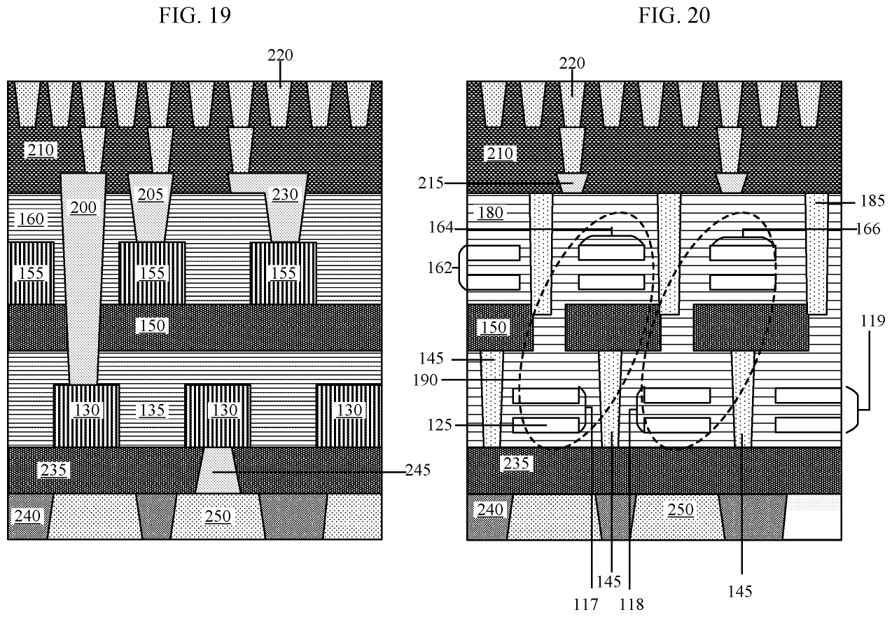

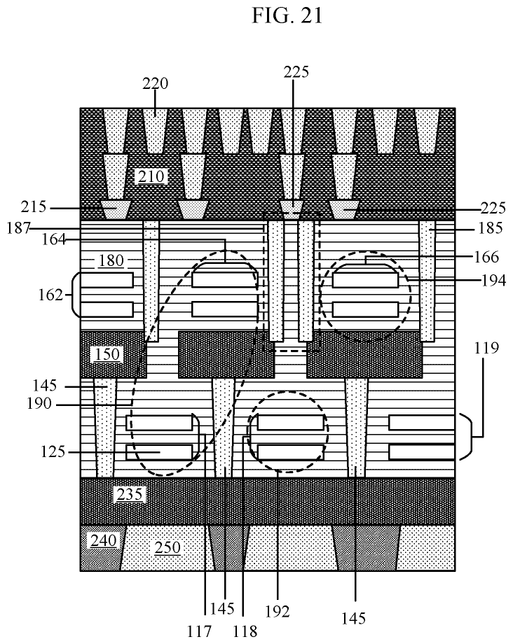

FIGS. 19, 20, and 21 illustrate another wiring option that some of the bottom S/D epis are connected to the backside interconnect through backside contacts. FIG. 19 illustrates a cross section Y₂ of the source/drain region of the offset stacked device after the formation of a source/drain contacts and electrical connections, in accordance with the embodiment of the present invention. FIG. 20 illustrates a cross section Y₁ of gate regions of the offset stacked device after the formation of a gate contacts and upper electrical connections, in accordance with the embodiment of the present invention. FIG. 21 illustrates a cross section Y3 of gate regions of the offset stacked device after the formation of a gate contacts and upper electrical connections, in accordance with the embodiment of the present invention. A top dielectric layer 210 is located on top of the top interlayer dielectric layer 160. One or more trenches (not shown) are formed in the top layer 210, the top interlayer dielectric layer 160, the bonding oxide 150, and the bottom interlayer dielectric layer 135 to expose a surface of the one or more bottom source drains 130. These trenches are filled with a conductive material to form the bottom source/drain contact 200. A second set of trenches are created in the top layer 210 and the top interlayer dielectric layer 160 to expose a surface of the upper source/drains 155. These trenches are filled with a conductive material to form the upper source/drain contacts 205 and 230. One of the lower source/drain contacts will be created as a backside contact 245, this allows for more flexibility to the design of the upper source/drain contacts 205, 230 since more space is available for the contact formation. This allows for flexibility of the shape of the upper source/drain contacts 205, 230 and allows for flexibility in forming the electrical connections 220 to said contacts. As such the upper source/drain contacts 205 and 230 can have different shapes.

One difference for this embodiment is that there is no shallow trench isolation layer 110, and buried oxide layer 235 was located between the substrate 105 and the components formed on the buried oxide layer 235. The offset device is flipped over (the figures do not illustrate the flipped over state) to allow for backside processing of the device. The substrate 105 is removed and a trench is formed in the buried oxide layer 235. The trench is filled with a conductive material to form the backside contact 245, where the backside contact 245 is in contact with a backside surface of one of the bottom source/drains 130. A backside layer 240 is formed on the buried oxide layer 235 and a power rail 250 is formed in the backside layer 240. The backside contact 245 is connected to the power rail 250.

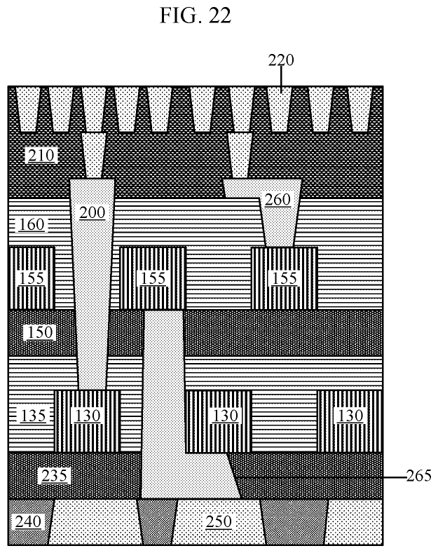

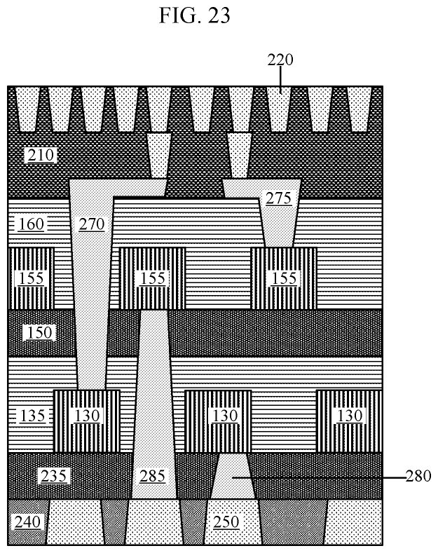

FIGS. 22 and 23 shows some additional options of wiring choices with backside interconnect. FIG. 22 illustrates a cross section Y₂ of the source/drain region of the offset stacked device after the formation of a source/drain contacts and electrical connections, in accordance with the embodiment of the present invention. A difference between FIG. 22 and FIG. 19, is that one of the upper source/drain contact 205 is relocated as a shared backside contact 265. The substrate 105 is removed and a shared trench (not shown) is formed in the buried oxide layer 235 to expose a backside surface of bottom source/drain 130. A via (not shown) is formed in the bottom interlayer dielectric layer 135 and the bonding oxide 150 to expose a backside surface of an upper source/drain 155. The shared trench and the via are connected to each other and filled a conductive metal to form a shared backside contact 265. The shared backside contact is connected to a backside of a bottom source/drain 130 and connected to a backside of an upper source/drain 155. A backside layer 240 is formed on the buried oxide layer 235 and a power rail 250 is formed in the backside layer 240. The shared backside contact 265 is connected to the power rail 250.

FIG. 23 illustrates a cross section Y₂ of the source/drain region of the offset stacked device after the formation of a source/drain contacts and electrical connections, in accordance with the embodiment of the present invention. A difference between FIG. 23 and FIG. 19, is that one of the upper source/drain contact 205 is relocated as a backside upper source/drain contact 265. The substrate 105 is removed and a trench (not shown) is formed in the buried oxide layer 235 to expose a backside of the bottom source/drain 130. Another trench (not shown) is formed in the buried oxide layer 235, the bottom interlayer dielectric layer 135, and the bonding oxide 150 to exposes a backside surface of an upper source/drain 155. The trenches are filled with a conductive material to form the lower backside contact 280 and an upper backside contact 285, where the lower backside contact 280 is in contact with a backside surface of one of the bottom source/drains 130 and the upper backside contact 285 is on contact with a backside surface of one of the upper source/drains 155. A backside layer 240 is formed on the buried oxide layer 235 and a power rail 250 is formed in the backside layer 240. The lower backside contact 280 and the upper backside contact 285 are connected to the power rail 250.

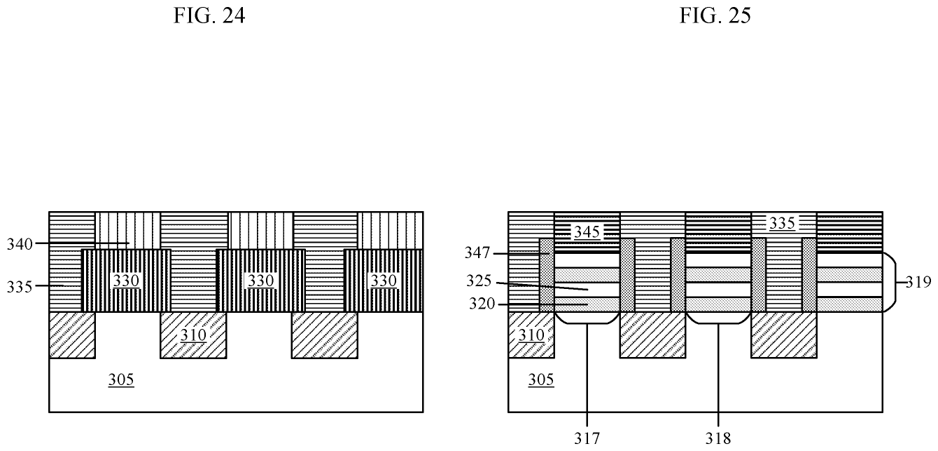

FIGS. 24 and 25 illustrate a process stage after formation of nanosheet active region (i.e., bottom nano stacks 317, 318, 319), and shallow trench isolation layer 310 followed by forming additional bottom sacrificial spacer 347 at sidewall of the nanosheet active region, followed by filling the remaining space with a bottom dielectric layer 335, followed by dummy gate 345, gate spacer (not shown), inner spacer (not shown), bottom source/drain epi 330 and interlayer dielectric layer 340 formation. FIG. 24 illustrates a cross section Y₂ of the source/drain region of the offset stacked device, in accordance with the embodiment of the present invention. FIG. 25 illustrates a cross section Y₁ and Y3 of gate regions of the offset stacked device, in accordance with the embodiment of the present invention.

The offset device includes a substrate 305, a shallow trench isolation layer 310, a first bottom nano stack 317, a second bottom nano stack 318, a third bottom nano stack 319, a bottom source/drain 330, a bottom dielectric layer 335, an interlayer dielectric layer 340, a bottom sacrificial spacer 347, and a dummy gate 345.

The substrate 305 can be, for example, a material including, but not necessarily limited to, silicon (Si), silicon germanium (SiGe), Si:C (carbon doped silicon), carbon doped silicon germanium (SiGe:C), III-V, II-V compound semiconductor or another like semiconductor. In addition, multiple layers of the semiconductor materials can be used as the semiconductor material of the substrate 305. In some embodiments, the substrate 305 includes both semiconductor materials and dielectric materials. The semiconductor substrate 305 may also comprise an organic semiconductor or a layered semiconductor such as, for example, Si/SiGe, a silicon-on-insulator or a SiGe-on-insulator. A portion or the entire semiconductor substrate 305 may also be comprised of an amorphous, polycrystalline, or monocrystalline. The semiconductor substrate 305 may be doped, undoped or contain doped regions and undoped regions therein.

Trenches (not shown) are formed in the substrate 305 when etching the layers to form the plurality of bottom nano stacks 317, 318, 319. These trenches are filled with a shallow trench isolation layer 310. The bottom nano stacks 317, 318, and 319 are located on top of the substrate 305.

Each of the plurality of bottom nano stacks 317, 318, 319 includes a plurality of sacrificial layers 320, and a plurality of channel layers 315 (i.e., nanosheets). The plurality of sacrificial layer 320 can be comprised of SiGe, where Ge is in the range of about 15% to 35%. One of the channel layers 315 is located above each of the sacrificial layers 320, and a hardmask layer (not shown) is used to pattern the bottom nano stacks 317, 318, 319. A bottom sacrificial spacer 347 is located on the sidewalls of each of the bottom nano stacks 317, 318, 319 and the bottom sacrificial spacer 347 extends partially up the sidewall of the dummy gate 345. A bottom dielectric layer 335 is located between each of the nano stacks 317, 318, 319, where the bottom dielectric layer 335 has a mushroom or T shape, meaning that a top section of the bottom dielectric layer 335 is located above the bottom spacer 347 achieved by filling the space with dielectric material followed by CMP stopping on hardmask layer. After that, the hard mask layer is removed. A dummy gate 140 is formed on top of each of the plurality of bottom nano stacks 317, 318, 319.

A plurality of bottom source/drains 330 are located on sections of the substrate 305. A section of interlayer dielectric layer 340 is in contact with a top surface of each of the plurality of the bottom source/drains 330. Furthermore, the interlayer dielectric layer 340 is located adjacent to and in direct contact with a bottom dielectric layer 335. The interlayer dielectric layer 340 does not extend to the horizontal ends of the bottom source/drain 300, as illustrated in FIG. 24. A bottom dielectric layer 335 is located between each of the bottom source/drains 330, where the bottom dielectric layer 335 has a mushroom or T shape. A top section of the bottom dielectric layer 335 is in direct contact with a top surface of the bottom source/drain 330 and in direct contact with a side surface of the interlayer dielectric layer 340.

The plurality of bottom source/drains 330 can be for example, a n-type epitaxy, or a p-type epitaxy. For n-type epitaxy, an n-type dopant selected from a group of phosphorus (P), arsenic (As) and/or antimony (Sb) can be used. For p-type epitaxy, a p-type dopant selected from a group of boron (B), gallium (Ga), indium (In), and/or thallium (Tl) can be used. Other doping techniques such as ion implantation, gas phase doping, plasma doping, plasma immersion ion implantation, cluster doping, infusion doping, liquid phase doping, solid phase doping, and/or any suitable combination of those techniques can be used. In some embodiments, dopants are activated by thermal annealing such as laser annealing, flash annealing, rapid thermal annealing (RTA) or any suitable combination of those techniques. A bottom interlayer dielectric layer 135 is located on top of the shallow trench isolation layer 110, and the bottom interlayer dielectric layer 135 surrounds each of the plurality of bottom source/drains 130.

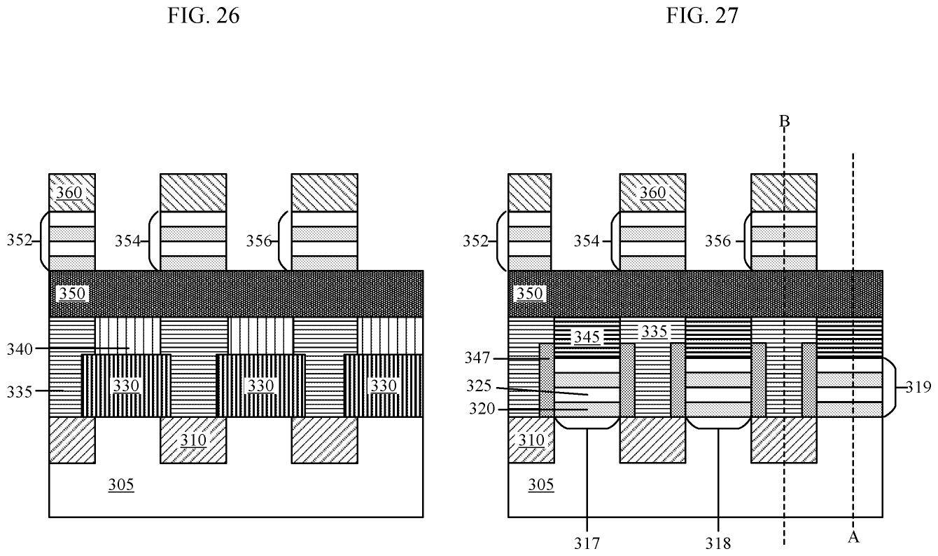

FIGS. 26 and 27 illustrate the process stage after bonding top channel materials followed by patterning process to define top active regions. FIG. 26 illustrates a cross section Y₂ of the source/drain region of the offset stacked device after the formation of a bonding oxide 350, and a plurality of upper nano stacks 352, 354, 356, in accordance with the embodiment of the present invention. FIG. 27 illustrates a cross section Y₁ and Y3 of gate regions of the offset stacked device after the formation of a bonding oxide 350, and a plurality of upper nano stacks 352, 354, 356, in accordance with the embodiment of the present invention. A bonding oxide 350 is formed on top of the bottom dielectric layer 335, the interlayer dielectric layer 340, and on top of the dummy gate 345. A plurality of upper nano stacks 352, 354, 356 are formed on top of the bonding oxide 350.

Each of the plurality of upper nano stacks 352, 354, 356, are comprised of a plurality of sacrificial layers 320, and a plurality of channel layers 325 (i.e., nanosheets). Each of the plurality of upper nano stacks 352, 354, 356, is offset from the one of the plurality of bottom nano stacks 317, 318, 319. The center vertical axis (i.e., B-axis) of each of the plurality of upper nano stacks 352, 354, 356, is not vertically aligned over the center vertical axis (i.e., A-axis) of the bottom nano stack 317, 318, 319. The center vertical axis (i.e., B-axis) of each of the plurality of upper nano stacks 352, 354, 356, can be aligned over one of the sections of the dielectric layer 335. A hardmask 360 is located on top of each of the plurality of upper nano stacks 352, 354, 356.

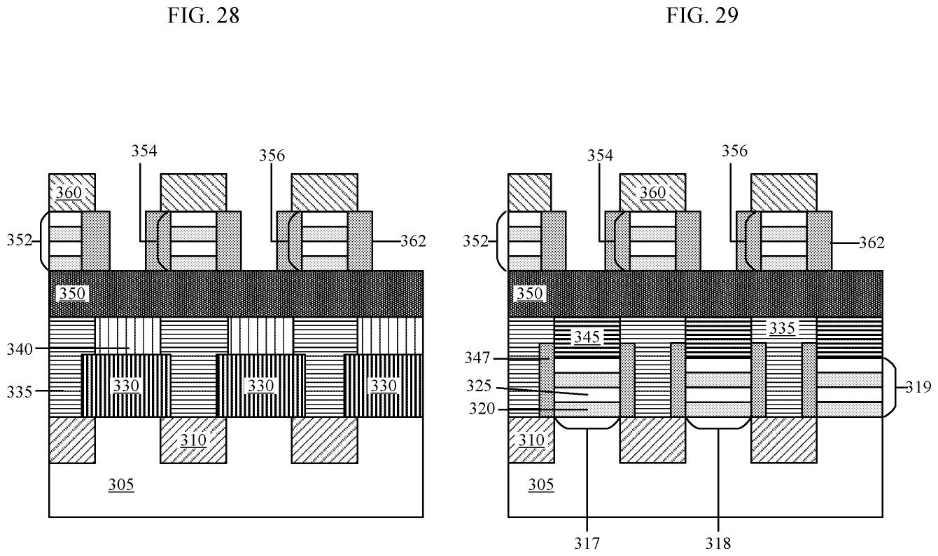

FIGS. 28 and 29 illustrate a process stage after the thinning of upper nano stacks followed forming sacrificial spacers. FIG. 28 illustrates a cross section Y₂ of the source/drain region of the offset stacked device after the thinning of upper nano stacks and formation of an upper sacrificial layer 362, in accordance with the embodiment of the present invention. FIG. 29 illustrates a cross section Y₁ and Y3 of gate regions of the offset stacked device after the thinning of upper nano stacks and formation of an upper sacrificial layer 362, in accordance with the embodiment of the present invention. The upper nano stacks 352, 354, 356 are thinned such that the ends of the hardmask 360 now extend past the ends of each of the plurality of upper nano stacks 352, 354, 356, respectively. An upper sacrificial layer 362 is grown from the sidewalls of each of the plurality of upper nano stacks 352, 354, 356. The upper sacrificial layer 362 can be comprised of, for example, SiGe. Part of the upper sacrificial layer 362 is located beneath the hardmask 360 and in contact with a bottom surface of the hardmask 360. Additionally, part of the upper sacrificial layer 362 extends beyond the end of the hardmask 360.

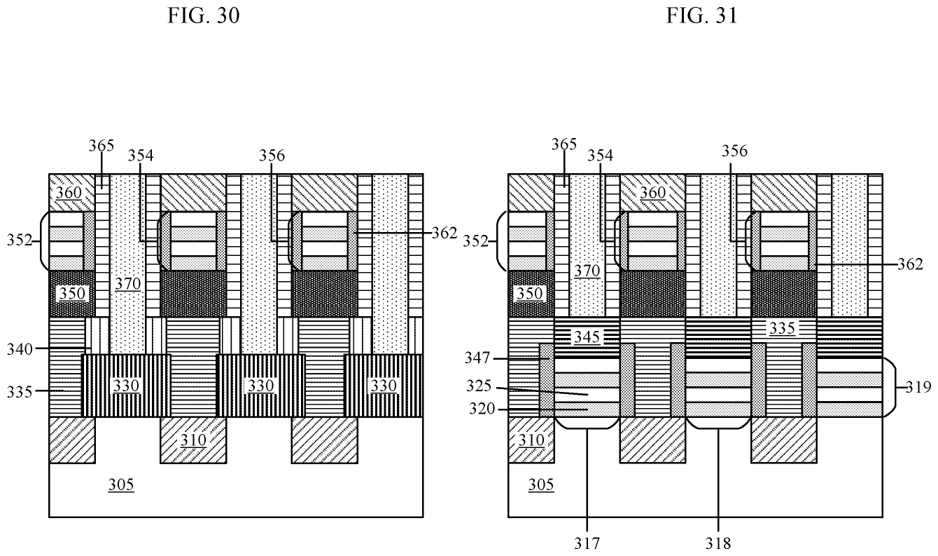

FIGS. 30 and 31 illustrate a process stage after removing the exposed sacrificial layer 362 and bonding oxide 350 that are not covered by hardmask 360, followed by formation of an upper dielectric spacer 365 and a dielectric core 370. FIG. 30 illustrates a cross section Y₂ of the source/drain region of the offset stacked device after formation of an upper dielectric spacer 365 and a dielectric core 370, in accordance with the embodiment of the present invention. A trench (not shown) is formed in the upper sacrificial layer 362 and in the bonding oxide 350 between the upper nano stacks 352, 354, 356, where the trench exposes a surface of the interlayered dielectric layer 340. The trench breaks the bonding oxide 350 into multiple sections. Upper dielectric spacer 365 material is formed on the exposed surfaces and is etched back so that the bottom of the upper dielectric spacers 365 is located on the sidewalls of the trench. Vertical pillars of the upper dielectric spacer 365 remain after the etch back process, where the remaining upper dielectric spacer 365 is located adjacent to the bonding oxide 350, the upper sacrificial layer 362, and the hardmask 360. The center of trench (not shown) is extended downwards to expose a top surface of the bottom source/drains 330. A dielectric core 370 is formed by filling the extended trench with a dielectric material, where the bottom of the dielectric core 370 is in direct contact with a top surface of the bottom source/drain 330. The dielectric core 370 is located between sections of the upper dielectric spacer 365 and between sections of the interlayer dielectric layer 340.

FIG. 31 illustrates a cross section Y₁ and Y3 of gate regions of the offset stacked device after formation of an upper dielectric spacer 365 and a dielectric core 370, in accordance with the embodiment of the present invention. A trench (not shown) is formed in the upper sacrificial layer 362 and in the bonding oxide 350 between the upper nano stacks 352, 354, 356, where the trench exposes a surface of the interlayered dielectric layer 340. The trench breaks the bonding oxide 350 into multiple sections. Upper dielectric spacer 365 is formed on the exposed surfaces and is etched back so that the bottom of the upper dielectric spacer 365 is located on the sidewalls of the trench. Vertical pillars of the upper dielectric spacer 365 remain after the etch back process, where the remaining upper dielectric spacer 365 is located adjacent to the bonding oxide 350, the upper sacrificial layer 362, and the hardmask 360. A dielectric core 370 is formed by filling the trench with a dielectric material, where the bottom of the dielectric core 370 is in direct contact with a top surface of the dummy gate 345.

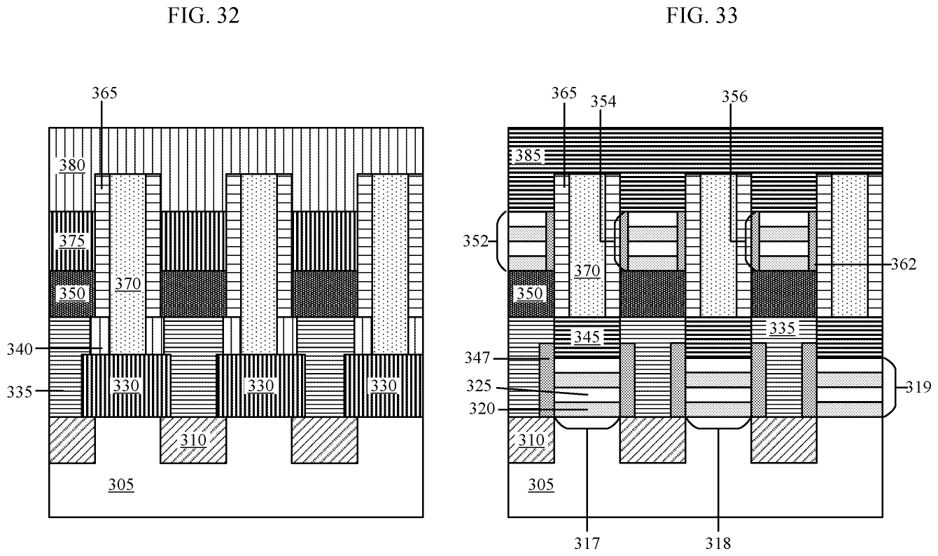

FIGS. 32 and 33 illustrate a process stage after removing the hardmask 360, forming the upper dummy gate 385, gate spacer/inner spacer (not shown), upper source/drains epi 375, and upper interlayer dielectric layer 380. FIG. 32 illustrates a cross section Y₂ of the source/drain region of the offset stacked device after the formation of a plurality of upper source/drains 375 and the upper interlayer dielectric layer 380, in accordance with the embodiment of the present invention. The hardmask 360 is removed, dummy gate, gate spacer are formed, and the upper nano stacks 352, 354, 356 are recessed back, followed by inner spacer formation. A plurality of upper source/drains 375 are formed where the upper nano stacks 352, 354, 356 are recessed. The dielectric core 370 and the dielectric spacer 365 extend vertically higher than a top surface of each of the upper source/drain 375. An upper interlayer dielectric 380 is formed on top of the upper source/drains 375, the upper dielectric spacer 365, and the dielectric core 370.

FIG. 33 illustrates a cross section Y₁ and Y3 of gate regions of the offset stacked device after formation of an upper dummy gate 385, in accordance with the embodiment of the present invention. The hardmask 360 is removed and the dielectric core 370 and the dielectric spacer 365 extend vertically higher than each of the upper nano stacks 352, 354, 356. An upper dummy gate 385 is formed on top of each of the upper nano stacks 352, 354, 356, the upper dielectric spacer 365 and the dielectric core 370.

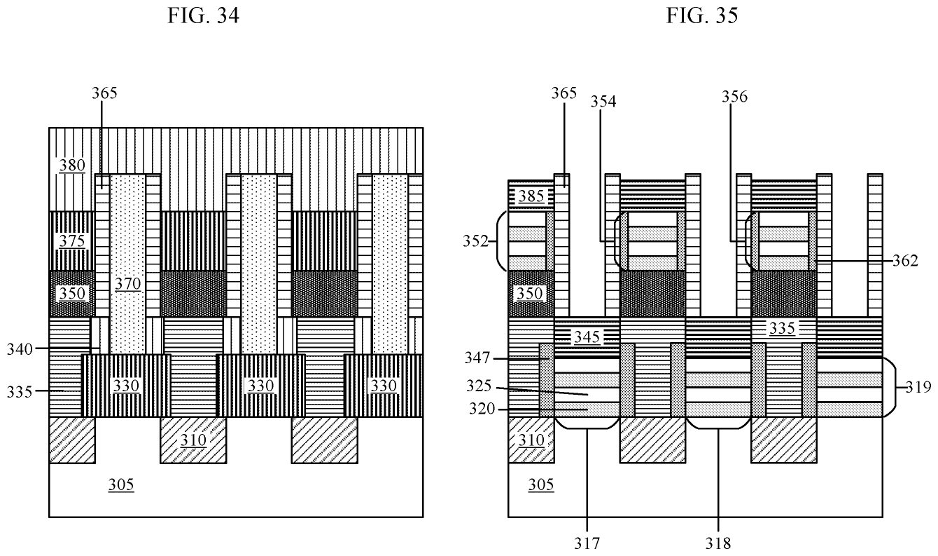

FIGS. 34 and 35 illustrate a process stage after recessing the top portions of the upper dummy gate, followed by removal of the dielectric core 370 to expose the bottom dummy gate 345. FIG. 34 illustrates a cross section Y₂ of the source/drain region of the offset stacked device after the recess of the upper dummy gate 385 and removal of the dielectric core 370 in the gate region, in accordance with the embodiment of the present invention. FIG. 35 illustrates a cross section Y₁ and Y3 of gate regions of the offset stacked device after the recess of the upper dummy gate 385 and removal of the dielectric core 370, in accordance with the embodiment of the present invention. The upper dummy gate 385 is not completely removed, a portion of the upper dummy gate 385 remains located on top of each of the upper nano stacks 352, 354, 356. The removal of the dielectric core 370 exposes a top surface of the dummy gate 345. At this stage the upper interlayer dielectric 380 is not etch or thinned, so the dielectric cores 370 located in the source/drain region are not removed, while the dielectric core 370 located in the gate region are removed.

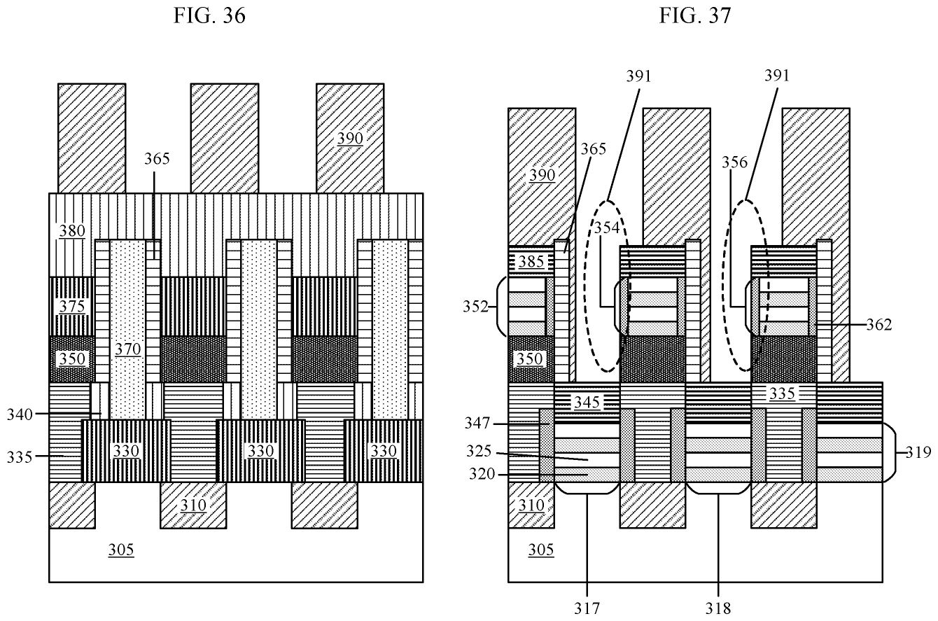

FIGS. 36, 37 and 38 illustrate a process stage after a patterning process to remove some of the upper dielectric spacer 365. FIG. 36 illustrates a cross section Y₂ of the source/drain region of the offset stacked device after the formation of a lithography layer 390 and the removal of some of the upper dielectric spacers 365, in accordance with the embodiment of the present invention. A lithography layer 390 is formed on the exposed surfaces and patterned. The pattering causes some of the upper dielectric spacer 365 to be removed. The patterning of the lithography layer 390 determines which of the upper dielectric spacers 365 that will remain and which ones that will be removed. The removal or non-removal of the upper dielectric spacer 365 will determine if a shared gate device or an independent gate device will be created.

FIG. 37 illustrates a cross section Y₁ of gate regions of the offset stacked device after the formation of a lithography layer and the removal of some of the upper dielectric spacers, in accordance with the embodiment of the present invention. A lithography layer 390 is formed on the exposed surfaces and patterned. The pattering causes some of the upper dielectric spacer 365 to be removed. As seen by dashed circle 391 some of the upper dielectric spacers 365 that are located between the upper nano stacks 352, 354, 356 are removed. The removal of the upper dielectric spacer 365 determines if a shared gate device or and independent gate device is formed, since the upper dielectric spacer 365 acts as a gate cut, which will be described in further detail below.

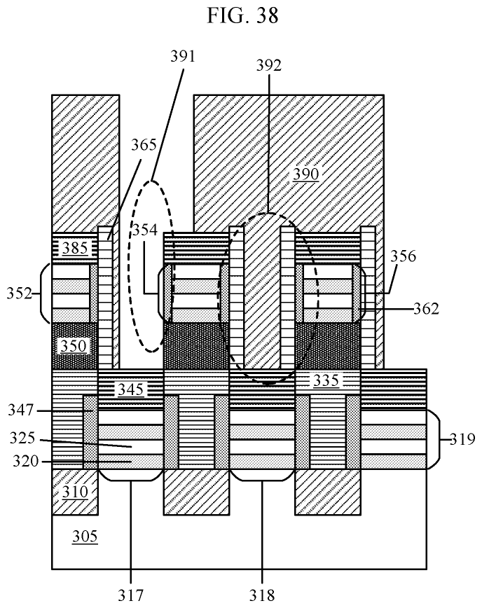

FIG. 38 illustrates a cross section Y3 of gate regions of the offset stacked device after the formation of a lithography layer 390 and the removal of some of the upper dielectric spacers 365, in accordance with the embodiment of the present invention. A lithography layer 390 is formed on the exposed surfaces and patterned. The pattering causes some of the upper dielectric spacer 365 to be removed. As seen by dashed circle 391 one of the upper dielectric spacers 365 that is located between the upper nano stacks 352, 354, is removed. Furthermore, as seen by dashed circle 392, adjacent sections of the upper dielectric spacer 365 can be protected by the lithography layer 390. The removal of the upper dielectric spacer 365 determines if a shared gate device or and independent gate device is formed, since the upper dielectric spacer 365 acts as a gate cut, which will be described in further detail below. The removal of the upper dielectric spacer 365, as illustrated by dashed circle 391, will lead the creation of a shared gate device. The upper dielectric spacer 365 protected by the lithography layer 390, as illustrated by dashed circle 392, will lead to the creation of an independent gate device.

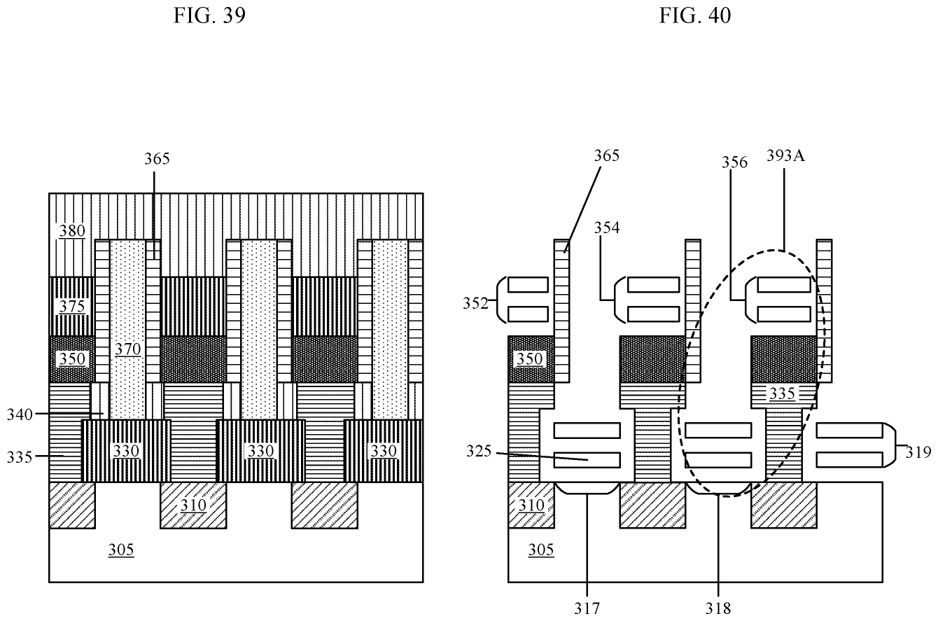

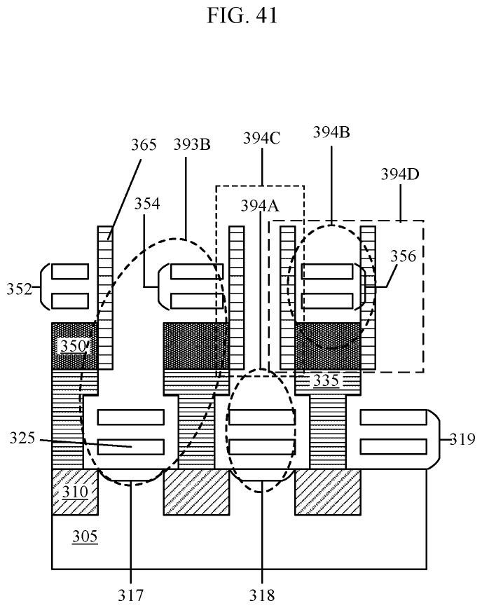

FIGS. 39, 40 and 41 illustrate a process stage after the removal of the upper dummy gate 385, the dummy gate 345, the sacrificial layers 320, the bottom spacer 347, and the upper sacrificial layer 362. FIG. 39 illustrates a cross section Y₂ of the source/drain region of the offset stacked device after the removal of the upper dummy gate 385, the dummy gate 345, the sacrificial layers 320, the bottom spacer 347, and the upper sacrificial layer 362, in accordance with the embodiment of the present invention. FIG. 40 illustrates a cross section Y₁ of gate regions of the offset stacked device after the removal of the upper dummy gate 385, the dummy gate 345, the sacrificial layers 320, the bottom spacer 347, and the upper sacrificial layer 362, in accordance with the embodiment of the present invention. FIG. 41 illustrates a cross section Y3 of gate regions of the offset stacked device after the removal of the upper dummy gate 385, the dummy gate 345, the sacrificial layers 320, the bottom spacer 347, and the upper sacrificial layer 362, in accordance with the embodiment of the present invention. The upper dummy gate 385, the dummy gate 345, the sacrificial layers 320, the bottom spacer 347, and the upper sacrificial layer 362 are removed. Dash circle 393A illustrates where the channel layers 315 between a second bottom nano stack 318 and the third upper nano stack 356 are connected by an empty space through the bonding oxide 350, as illustrated in FIG. 40. Dash circle 393B illustrates where the channel layers 315 between a first bottom nano stack 317 and the second upper nano stack 354 are connected by an empty space, as illustrated in FIG. 41. Dashed circles 394A and 394B illustrate where the channel layers 315 of the second bottom nano stack 318 and the channel layers 315 of the third upper nano stack 356 are isolated from the channel layers 315 contained in other nano stacks. The channel layers 315 of the second bottom nano stack 318 are isolated by the pair of upper dielectric spacer contained in dashed box 394C. The channel layers 315 of the third upper nano stack 356 are isolated by the pair of upper dielectric spacer contained in dashed box 394D.

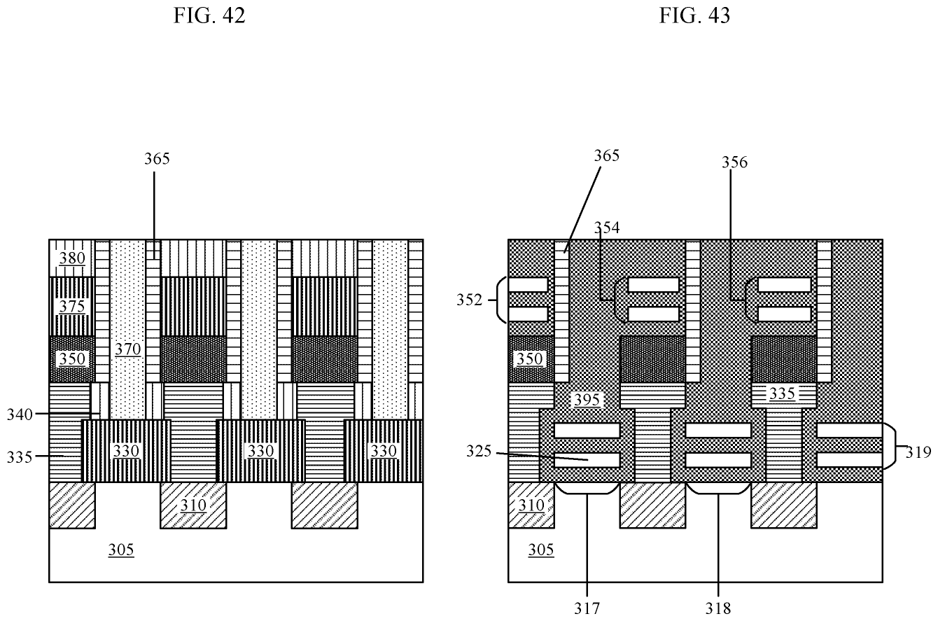

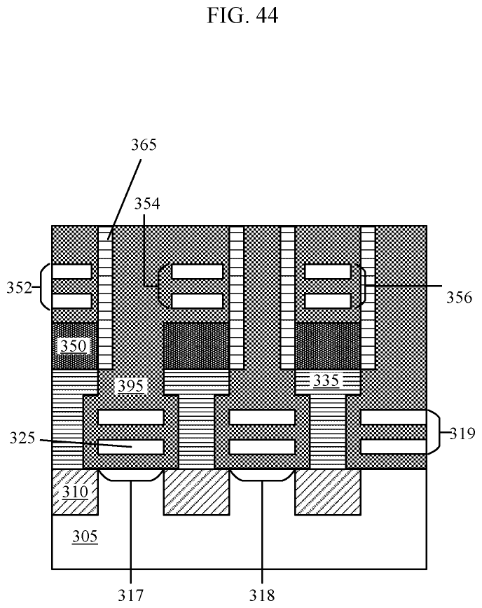

FIGS. 42, 43 and 44. illustrate a process stage after the formation of the gate 395. FIG. 42 illustrates a cross section Y₂ of the source/drain region of the offset stacked device after the formation of the gate 395, in accordance with the embodiment of the present invention. FIG. 43 illustrates a cross section Y₁ of gate regions of the offset stacked device after the formation of the gate 395, in accordance with the embodiment of the present invention. FIG. 44 illustrates a cross section Y3 of gate regions of the offset stacked device after the formation of the gate 395, in accordance with the embodiment of the present invention. A gate material is deposited to fill the space and surrounds the channel layers 315 to create the shared and independent gates 395. The gate 395 can be comprised of, for example, a gate dielectric liner, such as high-k dielectric like HfO₂, ZrO₂, HfLₐOₓ, etc., and work function layers, such as TiN, TiAlC, TiC, etc., and conductive metal fills, like W.

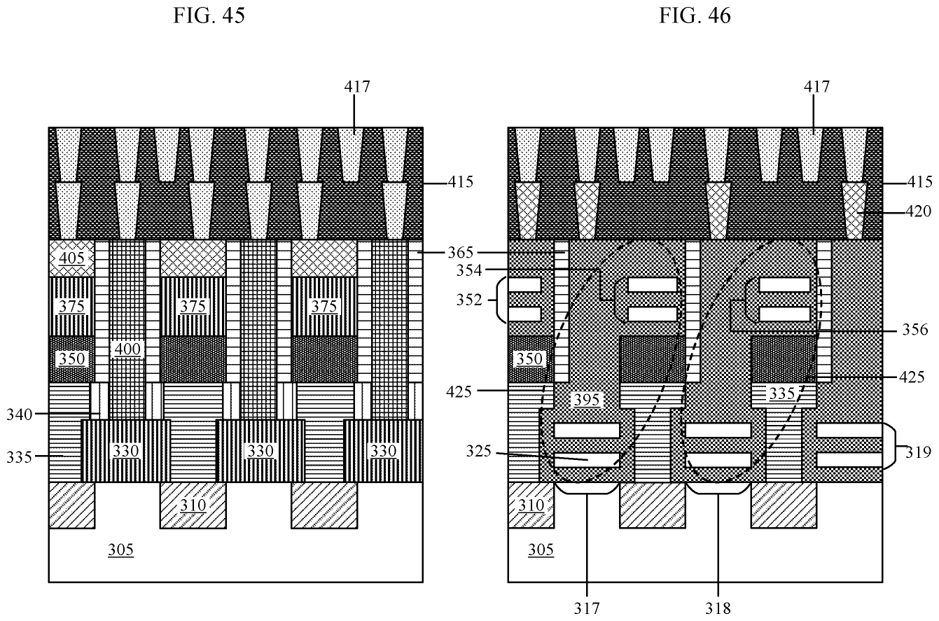

FIGS. 45, 46, 47 and 48 illustrate a process stage after formation of source/drain contacts and electrical connections. FIG. 45 illustrates a cross section Y₂ of the source/drain region of the offset stacked device after the formation of source/drain contacts and electrical connections, in accordance with the embodiment of the present invention. The upper interlayer dielectric layer 380 and the dielectric core 370 are removed to create an empty space. The upper sourced/drain contacts 405 and the lower source/drain contacts 400 are formed by filling the empty space with a conductive material. A section of the upper dielectric spacer 365 is located between each of the source/drain contacts to prevent the contacts from shorting each other. A top dielectric layer 415 is formed on top of the upper source/drain contacts 400, the lower source/drain contacts 400, and the upper dielectric spacer 365. Electrical connections 417 are formed in the top dielectric layer 415 and the electrical connections 417 are connected to the upper and lower source/drain contacts 400, 405.

FIG. 46 illustrates a cross section Y₁ of gate regions of the offset stacked device after the formation of gate contacts and electrical connections, in accordance with the embodiment of the present invention. The bottom dielectric layer 335 acts as a gate cut between the gates 395 located around each of the bottom nano stacks 317, 318, 319. The upper dielectric spacer 365 acts as gate cuts between the upper nano stacks 352, 354, 356. The upper dielectric spacers 365 be located to create shared gate devices or independent gate devices. Dashed circle 425 emphasizes share gate devices, meaning that the gate 395 is continuous between the lower nano stack 317, 318, and the upper nano stack 354, 356, respectively. A top dielectric layer 415 is formed on top of the gate 395 and on top of the upper dielectric spacer 365. Gate contacts 420 are formed in the top dielectric layer 415, where a gate contact 420 is connected to the gate 395 of each device. Electrical connections 417 are formed in the top dielectric layer 415 and connected to the gate contacts 420.

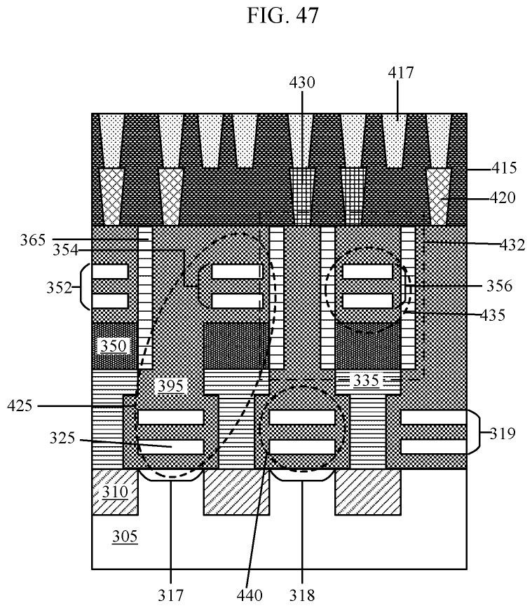

FIG. 47 illustrates a cross section Y3 of gate regions of the offset stacked device after the formation gate contacts and electrical connections, in accordance with the embodiment of the present invention. The bottom dielectric layer 335 acts as a gate cut between the gates 395 located around each of the bottom nano stacks 317, 318, 319. The upper dielectric spacer 365 acts as gate cuts between the upper nano stacks 352, 354, 356. The upper dielectric spacers 365 be located to create shared gate devices, for example, dashed circle 425 emphasizes a share gate device, meaning that the gate 395 is continuous between the lower nano stack 317 and the upper nano stack 354, respectively. Furthermore, the upper dielectric spacer 365 can be used to create independent gate devices. For example, dashed square 432 illustrate how the upper dielectric spacers 365 can be paired up to create the independent gate devices 435, 440. A top dielectric layer 415 is formed on top of the gate 395 and on top of the upper dielectric spacer 365. Gate contacts 420 are formed in the top dielectric layer 415, where a gate contact 420 is connected to the gate 395 of each device. Electrical connections 417 are formed in the top dielectric layer 415 and connected to the gate contacts 420.

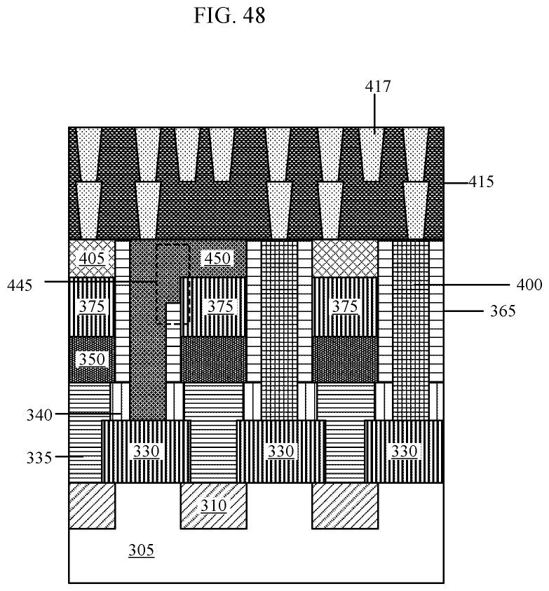

FIG. 48 illustrates a cross section Y₂ of the source/drain region of the offset stacked device after the formation of source/drain contacts and electrical connections, in accordance with the embodiment of the present invention. FIG. 48 illustrates a different configuration of the source/drain contacts than those illustrated in FIG. 45. The upper interlayer dielectric layer 380 and the dielectric core 370 are removed to create an empty space. Additionally, a portion of the upper dielectric spacer 365 is removed as illustrated by dashed box 445. The removal of the portion of the upper dielectric spacer 365 connects empty sections created by removal of a dielectric core 370 and upper interlayer dielectric layer 380. The empty spacer is connected to a surface of a lower source/drain 330 and an upper source/drain 375. The empty spaces are filled to create upper source/drain contacts, 405, lower source/drain contact 400, and shared source/drain contact 450. A top dielectric layer 415 is formed on top of the upper source/drain contacts 400, the lower source/drain contacts 400, the shared source/drain contract 450, and the upper dielectric spacer 365. Electrical connections 417 are formed in the top dielectric layer 415 and the electrical connections 417 are connected to the upper and lower source/drain contacts 400, 405 and the shared source/drain contact 450.

While the invention has been shown and described with reference to certain exemplary embodiments thereof, it will be understood by those skilled in the art that various changes in form and details may be made therein without departing from the spirit and scope of the present invention as defined by the appended claims and their equivalents.

The descriptions of the various embodiments of the present invention have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the one or more embodiment, the practical application or technical improvement over technologies found in the marketplace, or to enable others of ordinary skill in the art to understand the embodiments disclosed herein.

What is claimed is:

1. A microelectronic structure comprising:
a plurality of lower transistors and a plurality of upper transistors, wherein channels of the plurality of upper transistors are staggered from channels of the plurality of lower transistors; and
a lower dielectric pillar located beneath an upper transistor, wherein the dielectric pillar separates bottom transistors.

2. The microelectronic structure of claim 1, further comprising:
a bonding oxide located between the plurality of channels of the upper transistor and the lower dielectric pillar.

3. The microelectronic structure of claim 2, further comprising:
an upper dielectric pillar located adjacent to plurality of channels of an upper transistor, wherein the upper dielectric pillar separates the each of the plurality of upper transistors.

4. The microelectronic structure of claim 3, wherein a portion of the upper dielectric pillar is adjacent to the bonding oxide.

5. The microelectronic structure of claim 4, further comprising:
a first gate surrounds the channels of the lower transistor.

6. The microelectronic structure of claim 5, further comprising:
a second gate surrounds the channels of the upper transistor.

7. The microelectronic structure of claim 6, further comprising:
a gate connection located adjacent to the bonding oxide, wherein the gate connection is connected to the first gate and the second gate, wherein the combination of the first gate, the second gate, the gate connection forms a shared gate between the channels of the lower transistor and the channels of the upper transistor.

8. The microelectronic structure of claim 6, wherein the second gate is located between the channel layers of the upper transistor and the upper dielectric pillar.

9. The microelectronic structure of claim 1, further comprising:
a bottom dielectric layer located beneath the channel region of the lower transistors.

10. The microelectronic structure of claim 1, further comprising:
an upper source/drain associated with each of the plurality of upper transistors; and
a lower source/drain associated with each of the plurality of lower transistors.

11. The microelectronic structure of claim 10, further comprising:
an upper contact that is connected to the upper source/drain.

12. The microelectronic structure of claim 10, further comprising:
a lower contact that is connected to a top surface of the lower source/drain, wherein the lower contact is adjacent to the upper source/drain.

13. The microelectronic structure of claim 10, further comprising:
a shared contact that is connected to a top surface of the upper source/drain and connected to a top surface of the lower source/drain.

14. A microelectronic structure comprising:
a plurality of lower transistors and a plurality of upper transistors, wherein channels of the plurality of upper transistors are staggered from channels of the plurality of lower transistors;
a lower dielectric pillar located beneath an upper transistor, wherein the dielectric pillar separates bottom transistors; and
an independent gate surrounding the channels of a first lower transistor, wherein the independent gate is isolated from the other lower transistors and upper transistors.

15. The microelectronic structure of claim 14, further comprising:
a bonding oxide located between the plurality of channels of the upper transistor and the lower dielectric pillar.

16. The microelectronic structure of claim 15, further comprising:
an upper dielectric pillar located adjacent to the plurality of channels of an upper transistor, wherein the upper dielectric pillar separates the upper transistors.

17. The microelectronic structure of claim 16, wherein a first pair of upper dielectric pillars are located above the first lower transistor.

18. The microelectronic structure of claim 17, wherein the independent gate extends between the pair of upper dielectric pillars.

19. The microelectronic structure of claim 18, wherein a portion of the upper dielectric pillar is adjacent to the bonding oxide.

20. The microelectronic structure of claim 19, wherein a first upper transistor is located between a first upper dielectric pillar and a second upper dielectric pillar, wherein the first upper dielectric pillar is one of the dielectric pillars included in the pair of upper dielectric pillars.

21. The microelectronic structure of claim 20, further comprising:
a second independent gate surrounding the channels of the first upper transistor, wherein the second independent gate is isolated from the other lower transistors and upper transistors.

22. A microelectronic structure comprising:
a plurality of lower transistors and a plurality of upper transistors, wherein channels of the plurality of upper transistors are staggered from channels of the plurality of lower transistors;
a first independent gate surrounding the channels of a first lower transistor, wherein the first independent gate is isolated from the other lower transistors and upper transistors;
a second independent gate surrounding the channels of a first upper transistor, wherein the second independent gate is isolated from the other lower transistor and the upper transistors; and
a shared gate surrounding the channels of a second lower transistor and the channels of a second upper transistor.

23. A microelectronic structure comprising:
a plurality of lower transistors and a plurality of upper transistors, wherein channels of the plurality of upper transistors are staggered from channels of the plurality of lower transistors;
an upper source/drain associated with each of the plurality of upper transistors and a lower source/drain associated with each of the plurality of lower transistors;
a lower dielectric pillar located beneath an upper transistor, wherein the dielectric pillar separates bottom transistors;
an independent gate surrounding the channels of a first lower transistor, wherein the independent gate is isolated from the other lower transistors and upper transistors.

24. The microelectronic structure of claim 23, further comprising:
an upper contact that is connected to the upper source/drain; and
a lower contact that is connected to a top surface of the lower source/drain, wherein the lower contact is adjacent to the upper source/drain.

25. The microelectronic structure of claim 24, further comprising:
a shared contact that is connected to a backside surface of the upper source/drain and connected to a backside surface of the lower source/drain.
